(19) United States
(12) Patent Application Publication
(10) Pub. No.: US 2010/0091633 A1
(43) Pub. Date: Apr. 15, 2010

(54) METHOD FOR MANUFACTURING SEMICONDUCTOR DEVICE, SEMICONDUCTOR DEVICE AND OPTICAL PICKUP MODULE

(76) Inventors: Junya FuruyashikiI, Kagoshima (JP); Syouzou Moribe, Kagoshima (JP); Hiroki Utatsu, Kagoshima (JP); Noriyuki Yoshikawa, Osaka (JP); Toshiyuki Fukuda, Kyoto (JP); Masanori Minamio, Osaka (JP); Hiroyuki Ishida, Osaka (JP)

Correspondence Address: MCDERMOTT WILL & EMERY LLP, 600 13TH STREET, NW, WASHINGTON, DC, 20005-3096, US

(21) Appl. No.: 12/525,217

(22) PCT Filed: Mar. 10, 2008
(86) PCT No.: PCT/JP2008/000514

§ 371 Date: Jul. 30, 2009

(30) Foreign Application Priority Data
Mar. 14, 2007 (JP) 2007-064806

(51) Int. Cl. G11B 7/135; H01L 21/50; H01L 23/28

(52) U.S. Cl. 369/112.23; 438/113; 257/680; 369/112.01; 257/E21.499; 257/E23.116; G9B/11.057

(57) ABSTRACT

A flat pre-board plate including connection electrodes, internal interconnections, and external-connection portions is prepared. This pre-board plate is cut at portions each located between adjacent ones of the connection electrodes, thereby forming trenches. A plurality of semiconductor elements are placed in each of the trenches. Electrode pads and the connection electrodes are connected to each other by metal wires. Transparent lids are placed on, and bonded to, spacers to cover the semiconductor elements. Thereafter, two lines of the connection electrodes arranged between adjacent ones of the trenches are separated from each other. Subsequently, adjacent ones of the semiconductor elements are also separated from each other.

### TECHNICAL FIELD

The present invention relates to methods for fabricating semiconductor devices, semiconductor devices, and optical pickup modules.

### BACKGROUND ART

Conventional optical disk drives for reading signals from optical disks such as DVDs are provided with optical pickup modules in each of which a semiconductor laser for emitting light for reading, and a photodetector for receiving feedback light reflected from optical disks are mounted on the same base.

As disclosed in Patent Document 1, an optical disk drive includes an optical pickup module located under the optical recording surface of an optical disk and configured to move along the radius of the optical disk. Because of this configuration, size reduction of the optical disk drive requires miniaturization of the optical pickup module, which further requires miniaturization of the photodetector.

For example, Patent Document 2 discloses a method for fabricating a solid-state imaging device. This method is intended for miniaturization of a photodetector by reducing the size of a housing for accommodating a solid-state imaging element. Specifically, the method includes: resin-molding a housing including a base and rectangular frame-shaped ribs in one piece with a plurality of metal lead pieces, forming internal terminal portions and external terminal portions with the metal lead pieces; fixing an imaging element onto the base inside an internal space of the housing; connecting electrodes of the imaging element respectively to the inner terminal portions of the metal lead pieces; and fixing a transparent plate to an upper face of the ribs. In this method, in order to locate the transparent plate, a stepped portion is formed on the top face of the ribs, providing a lower step that is lowered along an internal periphery, the transparent plate has a size capable of being mounted onto an upper surface of the lower step within a region inward of an inner wall fanned by the stepped portion of the ribs, and when fixing the transparent plate to the upper face of the ribs, an adhesive is provided on the upper face of the lower step, then the transparent plate is placed on the adhesive to be fixed to the upper surface of the lower step while regulating its position with the inner wall of the stepped portion, and then the portion positioned outside the stepped portion of the ribs is removed.

### Patent Document 1: Japanese Laid-Open Patent Publication No. 2001-56950

### Patent Document 2: Japanese Laid-Open Patent Publication No. 2005-64292

### Patent Document 3: Japanese Laid-Open Patent Publication No. 2005-79537

### Patent Document 4: Japanese Laid-Open Patent Publication No. 2002-164524

### Patent Document 5: Japanese Laid-Open Patent Publication No. 2000-106377

### DISCLOSURE OF INVENTION

Problems that the Invention is to Solve

However, as illustrated in FIG. 31, in the solid-state imaging device disclosed in Patent Document 2, rectangular frame-shaped ribs 203 are provided on the external edges of a base 202 onto which an imaging element 205 is mounted. The four sides of the rectangular ribs 203 have an identical width, and thus miniaturization has limitations. The solid-state imaging device disclosed in Patent Document 3 has similar drawbacks. In a conventional fabrication method, a lead frame is placed as a base to be resin molded in one piece, thereby forming an original plate in which a plurality of housings are connected to each other, and then an imaging element is mounted. In this method, an expensive molding die is necessary, and ribs need to be formed in one piece with a lead frame by resin molding. In addition, in resin molding the ribs with the die, a small draft of 5 to 15° need to be provided on side surfaces of the ribs in order to take the product out of the die after the resin molding, and thus it was impossible to form vertical ribs. Further, the conventional method has a problem in which the design of the shape of the ribs cannot be easily changed because resin molding is performed with a die.

It is therefore an object of the present invention to provide a method for efficiently fabricating a semiconductor device which can be reduced in overall size, particularly in the length of a pair of two opposite sides out of the four sides of a substantially rectangular package.

### Means of Solving the Problems

To achieve the object, according to the present invention, a package with a new configuration has been devised in a method for fabricating a semiconductor device including a semiconductor element and a package on which the semiconductor element is mounted.

Specifically, a method for fabricating a semiconductor device according to the present invention includes the steps of: A: providing a plurality of parallel trenches in a flat pre-board plate, thereby forming a package-assembled board in which a plurality of packages are connected to one another; B: placing a plurality of semiconductor elements in each of the trenches in a direction along which the trench extends; and C: cutting the package-assembled board at a portion between adjacent two of the trenches.

In step A, at least two of the trenches are preferably formed at a time.

In step A, the trenches may be formed by mechanically digging in the pre-board plate or by digging in the pre-board plate with a laser.

In a preferred embodiment, the package-assembled board includes a plurality of connection electrodes arranged in two lines between adjacent two of the trenches along the trenches, in step B, the semiconductor elements and the connection electrodes are connected to each other by metal wires, and in step C, the two lines of the connection electrodes are separated from each other.

The method may further include the step of providing a ridge member extending along the trenches between the two lines of the connection electrodes. The ridge member herein is a member projecting from the upper surface of a side wall of a trench.

In a preferred embodiment, the method further includes the step of placing a lid for covering each of the semiconductor elements on the ridge member across an associated one of the trenches, and bonding the lid to the ridge member, after step B. Specifically, in a preferred embodiment, one lid is prepared for each semiconductor element, and the lid is placed on the ridge member across an associated one of the trenches, and bonded to the ridge member. An external edge portion of the lid is preferably located on the ridge member.

In another preferred embodiment, the method may further include the steps of: D: placing a transparent member having a plate shape on each of the semiconductor elements; and encapsulating the metal wires and a side wall surface of the transparent member with an encapsulating resin.

A semiconductor device according to the present invention includes a semiconductor element; and a package on which the semiconductor element is mounted. The semiconductor device is a substantially rectangular solid, and a bottom surface and a pair of opposite side surfaces of the semiconductor device are part of the package. The package includes a base which is substantially rectangular and has a mounting surface on which the semiconductor element is mounted, and ribs respectively provided on a pair of opposite external edges of the mounting surface and extending along the pair of opposite external edges. A plate-like transparent member is placed on the semiconductor element. The semiconductor element is encapsulated with an encapsulating resin. The base, the ribs, and the encapsulating resin are exposed at another pair of opposite side surfaces of the semiconductor device. The encapsulating resin and the transparent member are exposed at an upper surface of the semiconductor device. The phrase “the semiconductor device is a substantially rectangular solid” herein does not mean that the semiconductor device is a rectangular solid in the strict mathematical sense, and the rectangular solid may include strain or unevenness to some extent.

The transparent member may also be exposed at the another pair of opposite side surfaces of the semiconductor device.

An optical pickup module according to the present invention includes: one of the semiconductor devices described above; a laser module; and a beam splitter, wherein the lid is made of a transparent material, and the semiconductor element included in the semiconductor device is a photoreceiver.

The optical pickup module preferably includes a mirror and an objective lens, and is preferably placed under an information-recording surface of an optical disk. A direction along which the ribs extend is preferably substantially perpendicular to the information-recording surface.

The laser module preferably includes: a blue-violet laser device configured to emit light having a peak wavelength ranging from 385 nm to 425 nm, both inclusive; and a dual-wavelength laser device configured to emit light having a peak wavelength ranging from 630 nm to 670 nm, both inclusive, and light having a peak wavelength ranging from 760 nm to 800 nm, both inclusive. The peak wavelength of emitted light is a wavelength at which the intensity is at the maximum in a spectrum of the light.

### EFFECTS OF THE INVENTION

With a method for fabricating a semiconductor device according to the present invention, a plurality of parallel trenches are formed in a flat pre-board plate, and semiconductor elements are placed in these trenches. Accordingly, the length of the semiconductor device along the direction in which the trenches extend can be made substantially as small as the size of the semiconductor elements, thus efficiently fabricating a small-size semiconductor device.

### BRIEF DESCRIPTION OF DRAWINGS

FIG. 1(a) is a view, partially broken away, illustrating a semiconductor device according to a first embodiment. FIG. 1(b) is a view of the bottom in FIG. 1(a).

FIG. 2 shows fabrication of the semiconductor device of the first embodiment in chronological order.

FIG. 3(a) is a top view illustrating the semiconductor device of the first embodiment on the assumption that a lid is transparent. FIG. 3(b) is a cross-sectional view taken along line B-B′ in FIG. 3(a). FIG. 3(c) is a cross-sectional view taken along line A-A′ in FIG. 3(a). FIG. 3(d) is a partially enlarged view corresponding to FIG. 3(c).

FIG. 4(a) is a perspective view illustrating a semiconductor device according to a second embodiment. FIG. 4(b) is a cross-sectional view taken along line A-A′ in FIG. 4(a).

FIG. 5 shows fabrication of the semiconductor device of the second embodiment in chronological order.

FIG. 6(a) is a perspective view illustrating a semiconductor device according to a third embodiment. FIG. 6(b) is a cross-sectional view taken along line A-A′ in FIG. 6(a).

FIG. 7 is a perspective view illustrating another semiconductor device according to the second embodiment.

FIG. 8 is a perspective view illustrating another semiconductor device according to the third embodiment.

FIG. 9 is a perspective view illustrating another semiconductor device according to a fourth embodiment.

FIG. 10 shows fabrication of the semiconductor device of the fourth embodiment in chronological order.

FIG. 11 is a perspective view illustrating another semiconductor device according to a fifth embodiment.

FIG. 12(a) is a view, partially broken away, illustrating a semiconductor device according to a sixth embodiment. FIG. 12(b) is a view of the bottom in FIG. 12(a).

FIG. 13 shows fabrication of a package-assembled board of the sixth embodiment in chronological order.

FIG. 14 shows formation of trenches with laser light.

FIG. 15 shows fabrication of the semiconductor device of the sixth embodiment in chronological order.

FIG. 16(a) is a top view illustrating the semiconductor device of the sixth embodiment on the assumption that a lid is transparent. FIG. 16(b) is a cross-sectional view taken along line A-A′ in FIG. 16(a). FIG. 16(c) is a cross-sectional view taken along line B-B′ in FIG. 16(a).

FIG. 17(a) is a perspective view illustrating a semiconductor device according to a seventh embodiment. FIG. 17(b) is a cross-sectional view taken along line A-A′ in FIG. 17(a).

FIG. 18 shows fabrication of the semiconductor device of the seventh embodiment in chronological order.

FIG. 19 is a cross-sectional view illustrating a modification of the semiconductor device of the seventh embodiment.

FIG. 20(a) is a perspective view illustrating a semiconductor device according to an eighth embodiment. FIG. 20(b) is a cross-sectional view taken along line A-A′ in FIG. 20(a).

FIG. 21 is a perspective view illustrating another semiconductor device according to the sixth embodiment.

FIG. 22 is a perspective view illustrating another semiconductor device according to the seventh embodiment.

FIG. 23 is a cross-sectional view illustrating still another semiconductor device according to the seventh embodiment.

FIG. 24 is a perspective view illustrating another semiconductor device according to the eighth embodiment.

FIG. 25 is a perspective view illustrating a semiconductor device according to a ninth embodiment.

FIG. 26 is a perspective view illustrating a semiconductor device according to a tenth embodiment.

FIG. 27 is a perspective view illustrating an original plate for a package-assembled board with slits.

FIG. 28 is a perspective view illustrating a package-assembled board with slits.

FIG. 29 is a perspective view schematically illustrating an optical pickup module according to the second embodiment.

FIG. 30 is a front view schematically illustrating an optical pickup module according to the second embodiment.

FIG. 31 is a top view illustrating a conventional semiconductor device including a photoreceiver.

### DESCRIPTION OF SYMBOLS

1, 2, 3, 4, 5 semiconductor device

2′, 3′ semiconductor device

6, 7, 8, 9, 9′ semiconductor device

6′, 7′, 8′ semiconductor device

7a, 7b, 7a′, 7b′ semiconductor device

10 semiconductor element

22 metal wire

41 first laser device

42 second laser device

43 beam splitter

45 mirror

46 objective lens

47 optical disk

49 laser module

50, 150 package

55, 155 trench

60, 160 base

62, 162 mounting surface

64, 164 non-mounting surface

70, 170 rib

70a, 170a rib external side wall surface

70b, 170b rib upper surface

75, 175 connection electrode

76, 176 internal interconnection

77, 177 external-connection portion

80, 80′ spacer (ridge member)

80a, 180a spacer external side wall surface

85, 185 adhesive

90, 190 lid

90a, 190a lid side wall surface

94, 94′ transparent member

96, 196 encapsulating resin

100, 101, 102 package-assembled board

103 package-assembled board

122 metal wire

130 pre-board plate

180, 180′ spacer (ridge member)

194, 194′, 194a transparent member

### BEST MODE FOR CARRYING OUT THE INVENTION

Hereinafter, embodiments of the present invention will be specifically described with reference to the drawings. In the drawings, components having substantially the same functions are denoted by the same reference character for simplicity of the description.

### EMBODIMENT 1

### Semiconductor Device

Prior to description of a fabrication method according to a first embodiment, a semiconductor device fabricated with this method is described.

A semiconductor device fabricated with a fabrication method according to this embodiment is a photodetector employing an integrated photoreceiver as a semiconductor element. The semiconductor element may be a photoreceiver such as a photodiode, a phototransistor, and a photo IC, or a light-emitting element such as an LED and a semiconductor laser.

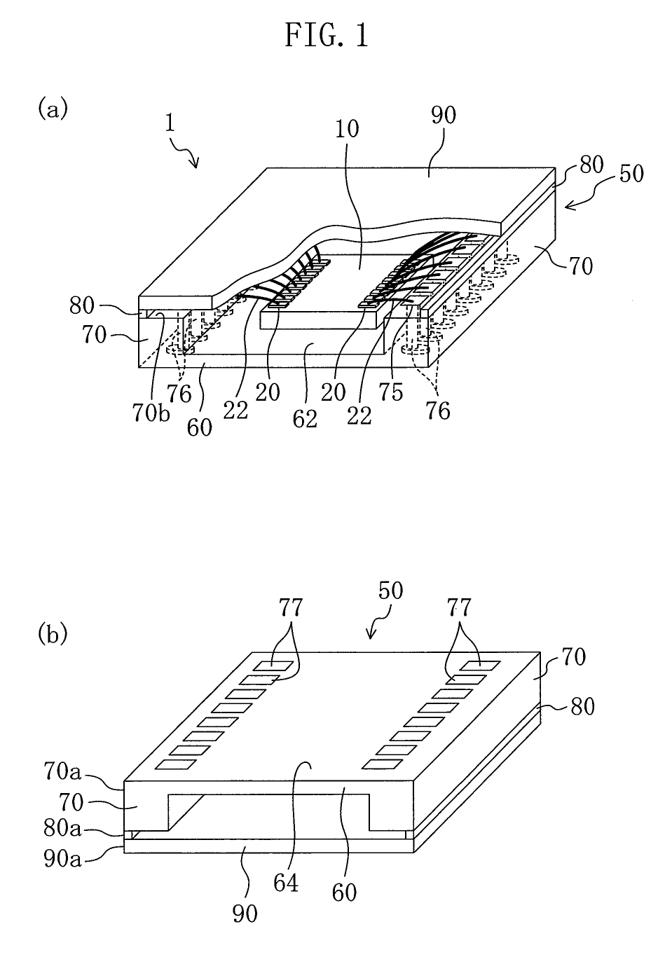

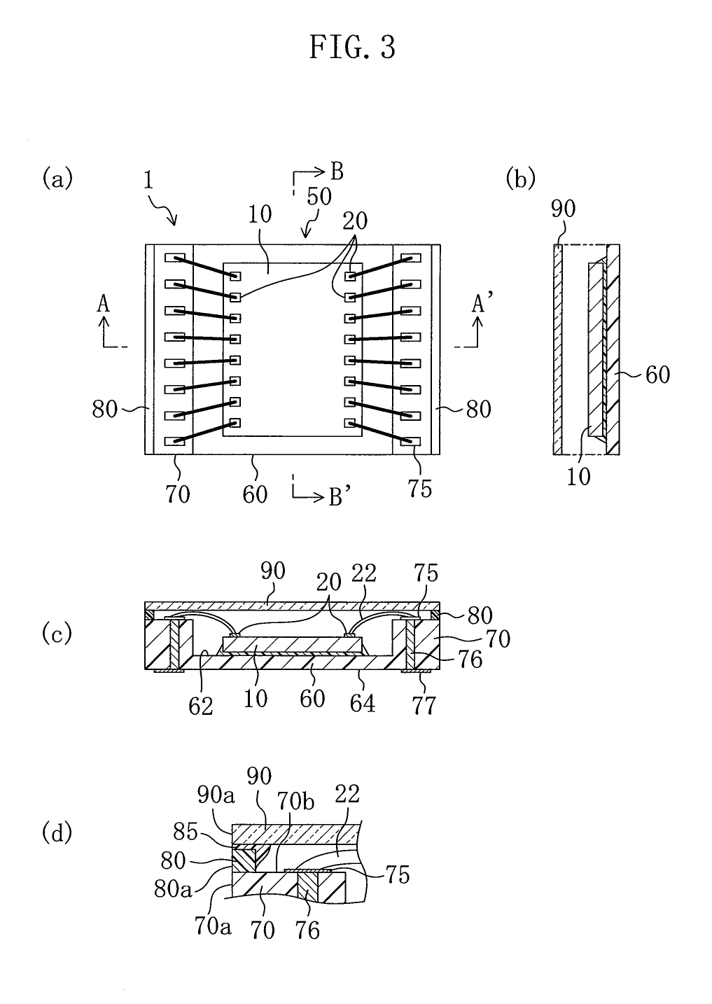

Specifically, as illustrated in FIG. 1, in a semiconductor device 1 of this embodiment, a semiconductor element 10 is housed in a recess of a recessed package 50 having a “U” shape in cross section, and a transparent flat lid 90 covers the recess. FIGS. 3(a) through 3(d) also illustrate the semiconductor device 1 of this embodiment. For convenience of description, the lid 90 is not shown in FIG. 3(a) on the assumption that the lid 90 is transparent. In the same manner, an adhesive 85 fixing the lid 90 is not shown in FIGS. 3(a) and 3(c), for convenience of description.

The package 50 of this embodiment includes: a rectangular base 60; two ribs 70, 70 respectively extending along a pair of opposite sides of the rectangle; and spacers 80, 80 respectively provided on the upper surfaces of the ribs 70, 70. The ribs 70, 70 respectively project upward from a pair of opposite external edges of a rectangular mounting surface 62 of the base 60 on which the semiconductor element 10 is mounted. Each of the ribs 70, 70 is in the shape of a rectangular solid extending along the external edge of the mounting surface 62. The boundaries between the base 60 and the ribs 70, 70 are not clearly shown. However, since the ribs 70, 70 are placed on the base 60, the level of the mounting surface 62 can be defined as the boundaries.

A plurality of internal interconnections (i.e., buried interconnections) 76, 76, . . . are provided in each of the ribs 70, 70. The internal interconnections 76 are connected to connection electrodes 75 at the rib upper surface 70b, and are connected to external-connection portions 77 at the opposite surface (i.e., a non-mounting surface 64). The spacers 80, 80 are located closer to the outside than the connection electrodes 75 on the rib upper surfaces 70b, and respectively extend in parallel with the ribs 70, 70. The spacers 80, 80 are ridge members rising upward from the rib upper surfaces 70b and formed in streaks.

The semiconductor element 10 is rectangular, and a plurality of electrode pads 20, 20, . . . are respectively aligned along a pair of two opposite sides of the semiconductor element 10 on one surface of the semiconductor element 10. The surface of the semiconductor element 10 opposite the surface on which the electrode pads 20, 20, . . . are provided is placed on the mounting surface 62, and is fixed to the mounting surface 62 with an adhesive. With this configuration, the semiconductor element 10 is mounted on the package 50 in such a manner that the electrode pads 20, 20, . . . are aligned substantially in parallel with the direction along which the ribs 70, 70 extend. The electrode pads 20, 20, . . . are connected to the connection electrodes 75 on the rib upper surfaces 70b by metal wires 22.

The spacers 80, 80 are located farther from the semiconductor element 10 than the connection electrodes 75 on the rib upper surfaces 70b, and extend in parallel with the ribs 70, 70. The lid 90 is placed on the spacers 80, 80, and is fixed thereto with an adhesive 85. The adhesive 85 is sandwiched between the spacers 80 and the lid 90. The adhesive 85 slightly extends out from the spacers 80 toward the inside of the package 50, but does not adhere to the metal wires 22. That is, the metal wires 22 are exposed to air except for portions thereof in contact with the connection electrodes 75 and with the electrode pads 20. In this regard, this embodiment differs from the technique disclosed in Patent Document 4.

In the technique of Patent Document 4, the absence of spacers prevents accurate positioning of the lid in teems of height, resulting in a problem in parallelizing the lid. In addition, as another problem, a difference in expansion coefficient between the adhesive and metal causes breaks in the metal wires at the boundary between portions of the metal wires buried in the adhesive, and portions of the metal wires exposed to air. In contrast, such problems do not arise in this embodiment. Moreover, in the semiconductor device of Patent Document 4, bonding wires are not fixed yet in bonding the transparent lid, but float in the adhesive in the state of a liquid. Accordingly, while this adhesive is hardened, contraction stress due to the hardening is applied to the bonding wires and connection portions between the bonding wires and the electrodes, and might cause peeling of the connection portions. In contrast, such a problem does not arise in this embodiment.

As illustrated in FIG. 3(d) that is an enlarged view of an upper portion of the left rib 70 in FIG. 3(c), the height of the spacers 80, 80 is greater than the diameter of the metal wires 22, and bonding of the metal wires 22 to the connection electrodes 75 is the second bonding. Thus, it is possible to prevent the lid 90 placed on the spacers 80, 80 from being in contact with the metal wires 22 and pushing the metal wires 22, resulting in high connection reliability of the metal wires 22. In addition, since the height of the spacers 80, 80 is set less than or equal to twice as large as the diameter of the metal wires 22, the thickness of the semiconductor device 1 can be reduced, resulting in miniaturization of the semiconductor device 1. Further, the length of the semiconductor device 1 along which the ribs 70, 70 extend can be reduced to be substantially equal to the length of the semiconductor element 10.

At each side wall surface of the semiconductor device 1, a rib external side wall surface 70a, a spacer external side wall surface 80a, and a lid side wall surface 90a are flush with one another. Accordingly, the length of the semiconductor device 1 between the ribs 70, 70 can be reduced, thus contributing to miniaturization. In addition, the adhesive 85 is also flush with these side wall surfaces, i.e., does not extend out from the side wall surface of the semiconductor device 1 outward. The external side wall surfaces herein refer to side wall surfaces of the ribs 70, 70 and the spacers 80, 80 opposite side wall surfaces thereof facing the semiconductor element 10.

### Method for Fabricating Semiconductor Device

A method for fabricating a semiconductor device 1 according to this embodiment is now described.

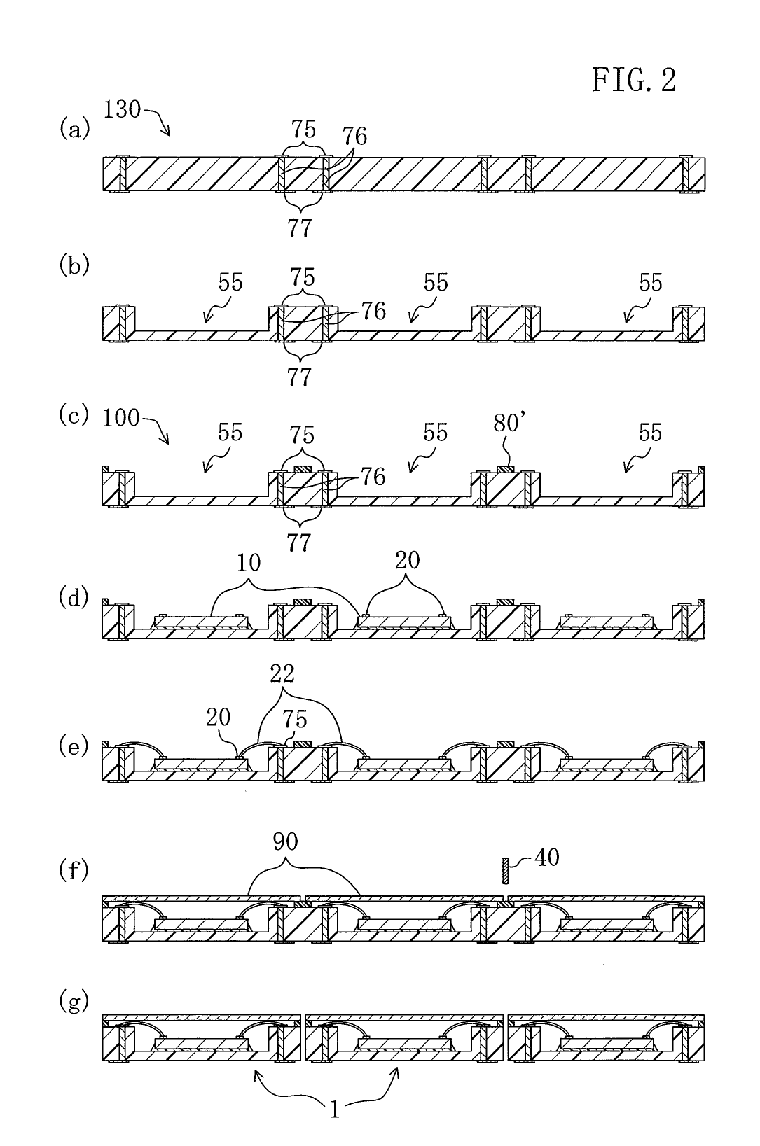

First, a pre-board plate 130 illustrated in FIG. 2(a) is prepared. The pre-board plate 130 actually further extends in the vertical and horizontal direction in FIG. 2(a), but only part of the pre-board plate 130 is shown in the drawings. The pre-board plate 130 is a flat plate made of a resin such as a glass epoxy resin or a BT resin. A plurality of internal interconnections 76, 76, . . . are buried in the pre-board plate 130. Connection electrodes 75, 75, . . . located on the internal interconnections 76, 76, . . . are formed on one surface of the pre-board plate 130, whereas external-connection portions 77, 77, . . . located on the internal interconnections 76, 76, . . . are formed on the other surface of the pre-board plate 130. The pre-board plate 130 is rectangular, and the internal interconnections 76, 76, . . . are arranged in lines in parallel with one side of the rectangle. Two types of distances, i.e., a large distance and a small distance, are alternately provided between adjacent lines of the internal interconnections 76, 76. The connection electrodes 75, 75, . . . and the external-connection portions 77, 77, . . . are also arranged in lines in the same manner as the internal interconnections 76, 76, . . . .

Next, a plurality of trenches 55, 55, . . . are formed in the pre-board plate 130. The trenches 55 are formed, by mechanically cutting the pre-board plate 130, between adjacent lines of the internal interconnections 76, 76, . . . disposed at the large distance in parallel with these lines. One or a plurality of trenches 55 are processed at a time with an end mill. In this processing, the pre-board plate 130 is linearly cut from one end to the other. The type of the end mill, and the rotation speed, feed speed, cutting depth, and cutting oil, which are cutting conditions, are determined depending on the size of, and material for, the pre-board plate 130, and are adjusted in such a manner that burrs, chatter marks, and dents do not occur on the processed surface. In this manner, the state illustrated in FIG. 2(b) is obtained.

Then, spacers 80′ as ridge members are provided between adjacent lines of the internal interconnections 76, 76 disposed at the small distance in parallel with these lines. That is, the spacers 80′ are provided on portions not subjected to the cutting. In this manner, a package-assembled board 100 illustrated in FIG. 2(c) is obtained. In the package-assembled board 100, a plurality of packages 50 as described above are arranged, and rib external side wall surfaces 70a of adjacent ones of the packages 50 are united. In the direction along which the ribs extend, a plurality of packages 50 are also arranged and united.

Next, a plurality of semiconductor elements 10 are mounted on, and fixed to, each of the bottom surfaces of the trenches 55, 55, . . . along the direction in which the trenches 55, 55, . . . extend. In this manner, the configuration illustrated in FIG. 2(d) is obtained.

Then, electrode pads 20 of the semiconductor elements 10 are wire bonded to the connection electrodes 75. In this manner, as shown in FIG. 2(e), a configuration in which the electrode pads 20 and the connection electrodes 75 are connected by metal wires 22 is obtained.

Thereafter, an adhesive (not shown) is applied onto the upper surfaces of the spacers 80′. Then, transparent lids 90 for the respective semiconductor elements 10 are placed on the spacers 80′, and are bonded and fixed to the spacers 80′. Each of the lids 90 covers an associated one of the semiconductor elements 10. This configuration is shown in FIG. 2(f). The adhesive is not shown in FIGS. 2(f) and 2(g).

Subsequently, the board is cut with a dicing saw 40 in such a manner that two lines of the connection electrodes 75, 75, . . . between adjacent two of the trenches 55, 55 are separated from each other. At this time, each of the spacers 80′ is divided into two at a middle portion thereof. In this manner, side wall surfaces become with one another. Thereafter, adjacent ones of the semiconductor elements 10 arranged perpendicularly to the direction along which the trenches 55 extend are separated from each other. In this manner, individual semiconductor devices 1 are obtained. This state in which the individual semiconductor devices 1 are obtained is shown in FIG. 2(g).

In the fabrication method of this embodiment, one or a plurality of trenches 55, 55, . . . are formed in the pre-board plate 130 at a time. Accordingly, a necessary number of the trenches 55 can be efficiently formed in the package-assembled board 100. In addition, the size of the package-assembled board 100 may be arbitrarily selected, and it is possible to easily fabricate, in a short period of time, even a large-size package-assembled board 100 on which a large number of semiconductor elements 10 can be mounted. As a result, small-size semiconductor devices 1 can be fabricated at low cost.

In the case of forming ribs by resin molding with a die in a conventional manner, a small draft of 5 to 15° need to be provided on side surfaces of the ribs. However, the ribs can be formed perpendicularly to the mounting surface for a semiconductor element. This structure can not only simplify the design but also allow for a convenient change in design of the rib width.

In addition, trenches can be formed only by operating an end mill, and thus one cut from one end of the pre-board plate 130 to the other end of the pre-board plate 130 enables formation of a package-assembled board 100. Accordingly, as compared to the case of surface processing, the processing time can be shortened, and process steps can be simplified because of unnecessity of postprocessing and finishing processing, thus leading to cost reduction.

The above-described method for fabricating semiconductor devices 1 is merely an example. The fabrication method of this embodiment is not limited to this example. After formation of the trenches 55, internal interconnections 76, 76, . . . and connection electrodes 75, 75, . . . , for example, may be provided. The lids 90 may be placed after the separation of two lines of the connection electrodes 75, 75, . . . . The trenches 55, 55, . . . may be formed by cutting, or by molding such as injection molding.

In the semiconductor device 1 of this embodiment, the connection electrodes 75 are not provided on the mounting surface 62 of the base 60, but are provided on the upper surfaces 70b of the ribs 70, 70 for placing the lid 90. This structure can reduce the size of the semiconductor device 1. In addition, the spacers 80, 80 provided on the ribs 70, 70 can increase the degree of parallelism of the lid 90.

### EMBODIMENT 2

### Semiconductor Device

A semiconductor device according to a second embodiment differs from the semiconductor device of the first embodiment in that a transparent member in the shape of a plate replaces the transparent flat lid and is placed on a semiconductor element, and that a trench in the package is filled with an encapsulating resin in such a manner that side surfaces of the transparent member and metal wires are buried in the resin. Now, the second embodiment, particularly aspects thereof different from those of the first embodiment, is described. The same aspects as those of the first embodiment may be omitted in the following description.

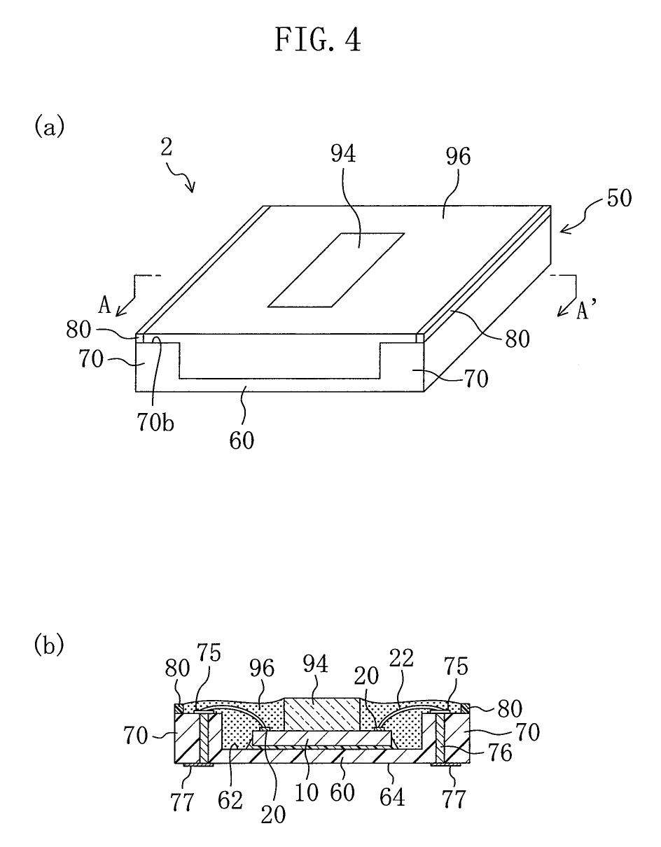

FIGS. 4(a) and 4(b) illustrate a semiconductor device 2 according to this embodiment. In this embodiment, a package 50, a semiconductor element 10, spacers 80, 80, ribs 70, 70, and metal wires 22 are the same as those in the first embodiment, and a configuration for connecting the semiconductor element 10 and connection electrodes 75 is also the same as that of the first embodiment.

The semiconductor element 10 mounted on the package 50 is connected to connection electrodes 75 by the metal wires 22. A plate-like transparent member 94 is placed on the semiconductor element 10 to cover the light-receiving surface of the semiconductor element 10 with a transparent adhesive interposed between the semiconductor element 10 and the transparent member 94. The transparent member 94 is a plate-like member having a rectangular upper surface and made of glass, and adheres to the semiconductor element 10. The bottom and upper surfaces of the transparent members 94 are smaller than the upper surface of the semiconductor element 10 and are slightly larger than the light-receiving region in such a manner that the transparent members 94 partially covers the upper surface of the semiconductor element 10.

In addition, components provided in a trench (recess) of the package 50 except for the upper surface of the transparent member 94 and the upper surfaces of the spacers 80, 80 are encapsulated with the encapsulating resin 96. Specifically, four side surfaces of the transparent member 94, the upper surfaces of the ribs 70, 70, and the metal wires 22, for example, are buried in the encapsulating resin 96. At a pair of opposite side surfaces of the semiconductor device 2 perpendicular to the direction in which the ribs 70, 70 extend, a base 60, the ribs 70, 70, and the encapsulating resin 96 are exposed.

When viewed from above the semiconductor device 2 of this embodiment, only the upper surface of the transparent member 94 and the upper surfaces of the spacers 80, 80 are exposed, and the other components are covered with the encapsulating resin 96. Accordingly, no dirt and dust accumulate on the light-receiving surface of the semiconductor element 10, electrode pads 20, the connection electrodes 75, and the metal wires 22, thus avoiding failures such as short circuits caused by dirt and dust. The encapsulating resin 96 is preferably one of a thermosetting epoxy resin, a filler-added resin containing, for example, SiO₂, and a resin which contains a dye and exhibits a light-blocking property, for example.

The encapsulating resin 96 is a high-viscosity liquid when filling the trench of the package 50, and is then cured. At the side wall surfaces of the semiconductor device 2 except for rib external side wall surfaces 70a, the encapsulating resin 96 is flush with the end surfaces of the ribs 70, 70. The height of the spacers 80, 80 is greater than the diameter of the metal wires 22. Accordingly, when the trench is filled with the encapsulating resin 96 to a level approximately equal to that of the upper surfaces of the spacers 80, 80, the metal wires 22 are completely buried in the encapsulating resin 96. Unlike the technique of Patent Document 4 with which only part of metal wires are buried in an encapsulating resin, the structure of this embodiment can prevent breaking of the metal wires 22, and thus connection portions between the metal wires 22 and the electrode pads 20 and between the metal wires 22 and the connection electrodes 75 are fixed, thus enhancing connection reliability. In addition, since the upper surface of the transparent member 94 is exposed and the side surfaces of the transparent member 94 are buried in the encapsulating resin 96, only light that has passed through the upper surface of the transparent member 94 reaches the light-receiving surface of the semiconductor element 10. Even when light enters the side surfaces of the transparent member 94, such light does not reach the light-receiving surface. Consequently, stray light (i.e., diffuse reflection of light) can be eliminated, and thus optical properties can be enhanced.

With respect to the height (i.e., distance) from the mounting surface 62 of the base 60, the height of the upper surface of the transparent member 94 is larger than that of the upper surfaces of the spacers 80, 80. Accordingly, in placing the semiconductor device 2 in an optical pickup module, the upper surface of the transparent member 94 that is parallel to the light-receiving surface of the semiconductor element 10 and has a large area can be easily used as a reference surface for the placement. In addition, accuracy in the placement in the optical pickup module can be easily enhanced. Further, the placement can be easily performed for a short period of time.

As the semiconductor device 1 of the first embodiment, the semiconductor device 2 of this embodiment can be made smaller than conventional semiconductor devices.

The spacers 80, 80 may be removed, as in a semiconductor device 2′ illustrated in

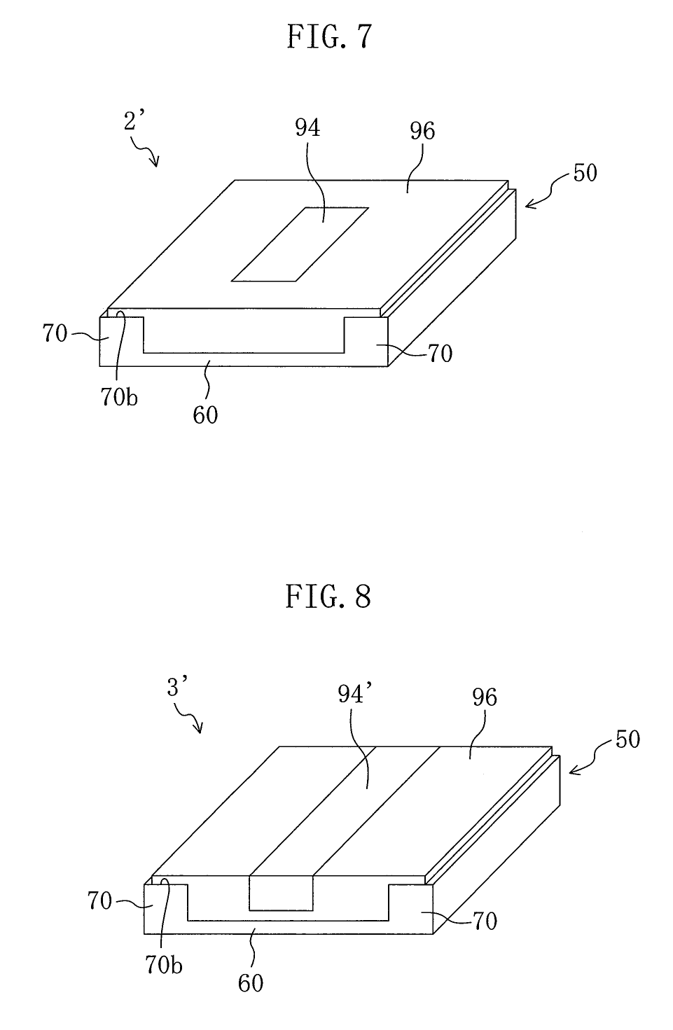

FIG. 7.

### Method for Fabricating Semiconductor Device

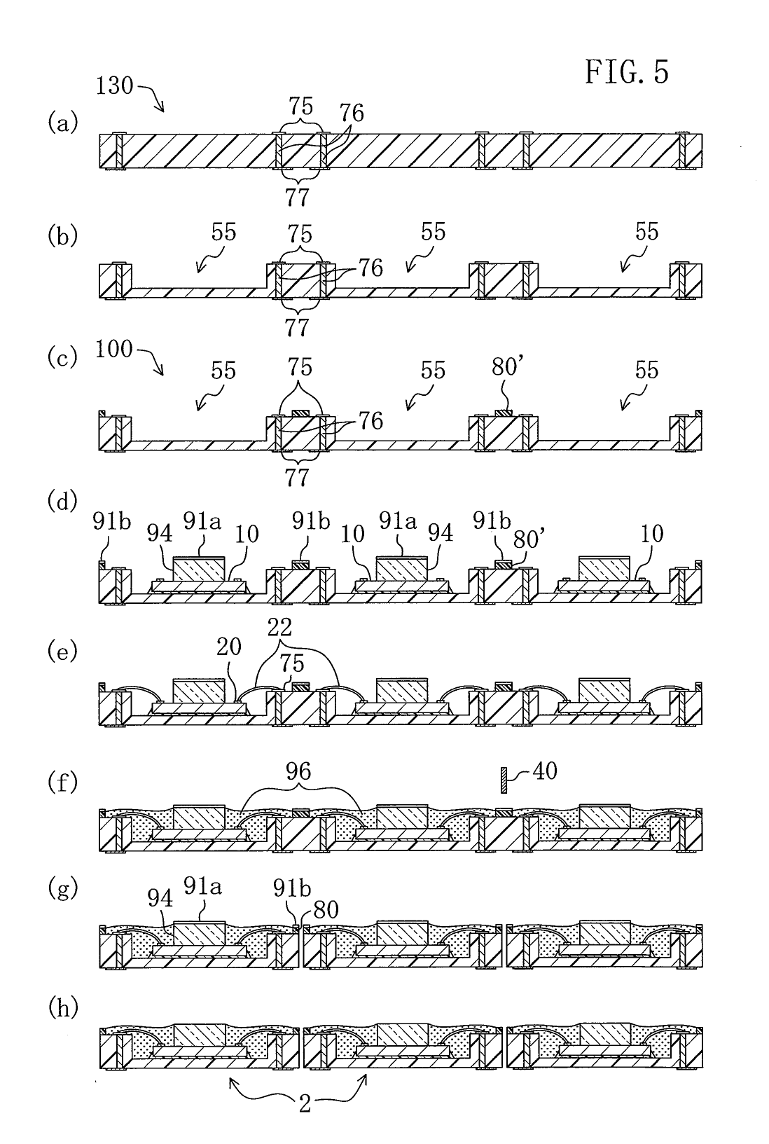

A method for fabricating a semiconductor device 2 according to this embodiment is now described with reference to FIGS. 5(a) through 5(h). Description of process steps already described in the fabrication method of the first embodiment is omitted or simplified.

Process steps shown in FIGS. 5(a) through 5(c) are the same as those of the first embodiment, and thus description thereof is omitted.

In the state shown in FIG. 5(c), a plurality of semiconductor elements 10 are sequentially placed on, and fixed to, the bottom surfaces of the trenches 55, 55, . . . along the direction in which the trenches 55, 55, . . . extend. Then, transparent members 94 are respectively placed on the light-receiving surfaces of the semiconductor elements 10, and are fixed with a transparent adhesive. At this time, protective sheets 91a are provided on the upper surfaces of the transparent members 94. Protective sheets 91b are then provided on the upper surfaces of the spacers 80′. In this manner, a configuration as illustrated in FIG. 5(d) is obtained.

Then, electrode pads 20 of the semiconductor elements 10 are wire bonded to connection electrodes 75. In this manner, as illustrated in FIG. 5(e), the electrode pads 20 and the connection electrodes 75 are connected to each other by metal wires 22.

Thereafter, the trenches 55 are filled with an encapsulating resin 96. This filling may be achieved by potting or injection molding. At this time, the entire upper surfaces of the transparent members 94 and the upper surfaces of the spacers 80′ are covered with the protective sheets 91a and 91b. This structure ensures that the upper surfaces of the transparent members 94 and the upper surfaces of the spacers 80′ are not covered with the encapsulating resin 96 and are exposed. FIG. 5(f) shows a state in which the encapsulating resin 96 fills the trenches, and is cured.

Subsequently, the board is cut with a dicing saw 40 in such a manner that two lines of the connection electrodes 75 between adjacent two of the trenches 55, 55 are separated from each other. At this time, each of the spacers 80′ is divided into two at a middle portion thereof. The state after the separation is shown in FIG. 5(g). In this manner, side wall surfaces are made flush with one another.

Then, the protective sheets 91a and 91b are peeled off from the transparent members 94 and the spacers 80. Thereafter, adjacent ones of the semiconductor elements 10 arranged perpendicularly to the direction along which the trenches 55 extend are separated from each other. In this manner, individual semiconductor devices 2 are obtained. This state is illustrated in FIG. 5(h). It should be noted that because of compression of the encapsulating resin 96 during curing, the upper surface of the encapsulating resin 96 is located several micrometers below the upper surfaces of the transparent members 94 and the upper surfaces of spacers 80.

The fabrication method of this embodiment has the same advantages as those of the fabrication method of the first embodiment.

### Optical Pickup Module

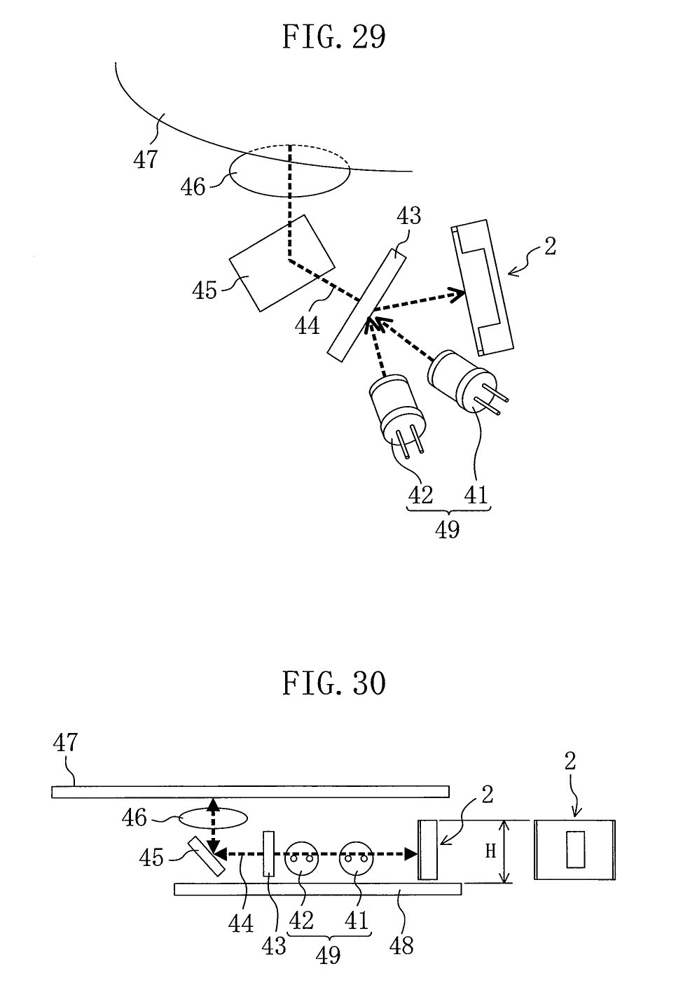

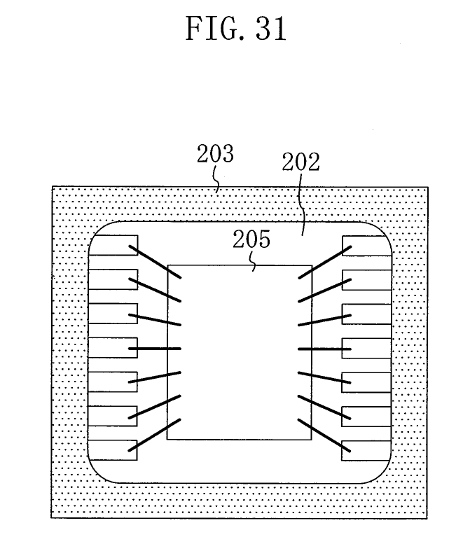

FIG. 29 is a perspective view schematically illustrating a configuration in which an optical pickup module according to this embodiment is placed under an optical disk 47. FIG. 30 is a side view of the configuration. The semiconductor device 2 at the right side of FIG. 30 is shown in order to depict the light-receiving surface of the semiconductor device 2 (photodetector) mounted on a support 48, which is located at the left of the right-side semiconductor device 2, with the semiconductor device 1 rotated 90° with respect to the vertical axis. The illustration does not mean that two semiconductor devices 2 are provided in the optical pickup module.

This optical pickup module includes the above-described semiconductor device 2 (photodetector), first and second laser devices 41 and 42, a beam splitter 43, a mirror 45, and an objective lens 46. The first and second laser devices constitute a laser module 49. Light 44 emitted from the first and second laser devices 41 and 42 passes through the beam splitter 43, is reflected on the mirror 45, and then strikes an information-recording surface of the optical disk 47 through the objective lens 46. The light 44 is then reflected on the information-recording surface, and enters the semiconductor device 2 by way of the objective lens 46, the mirror 45, and the beam splitter 43.

In this case, the first laser device 41 is a blue-violet laser device configured to emit laser light having a peak wavelength of 405 nm. The second laser device 42 is a dual-wavelength laser device configured to emit laser light with two wavelengths: red laser light having a peak wavelength of 650 nm; and infrared laser light having a peak wavelength of 780 nm.

Components constituting the optical pickup module are mounted on the support 48, and this support 48 is placed under the information-recording surface of the optical disk 47. Under the rotating optical disk 47, the optical pickup module moves along the radius of the optical disk 47. The surface of the support 48 on which the components are mounted is in parallel with the information-recording surface of the optical disk 47.

For convenience in establishing interconnection, the semiconductor device 2 is positioned in such a manner that the direction along which the ribs 70, 70 extend is perpendicular to the support 48, i.e., to the information-recording surface of the optical disk 47. With this positioning, a plurality of external-connection portions 77, 77, . . . of the semiconductor device 2 are arranged in two lines perpendicularly to the mounting surface of the support 48. Accordingly, wires drawn from the external-connection portions 77, 77, . . . to establish connection to the outside are arranged within the height H of the semiconductor device 2 from the mounting surface of the support 48, resulting in reduction of the height of the entire optical pickup module.

As described above, the ribs 70, 70 of the semiconductor device 2 extend perpendicularly to the support 48, and no ribs extend in parallel with the support 48. This configuration allows the height H of the semiconductor device 2 to be made approximately equal to the length of one side of the semiconductor element 10. As a result, the entire optical pickup module can be thinner, and smaller in size.

### EMBODIMENT 3

A semiconductor device according to a third embodiment differs from the semiconductor device 2 of the second embodiment in a transparent member, and thus different aspects thereof are described.

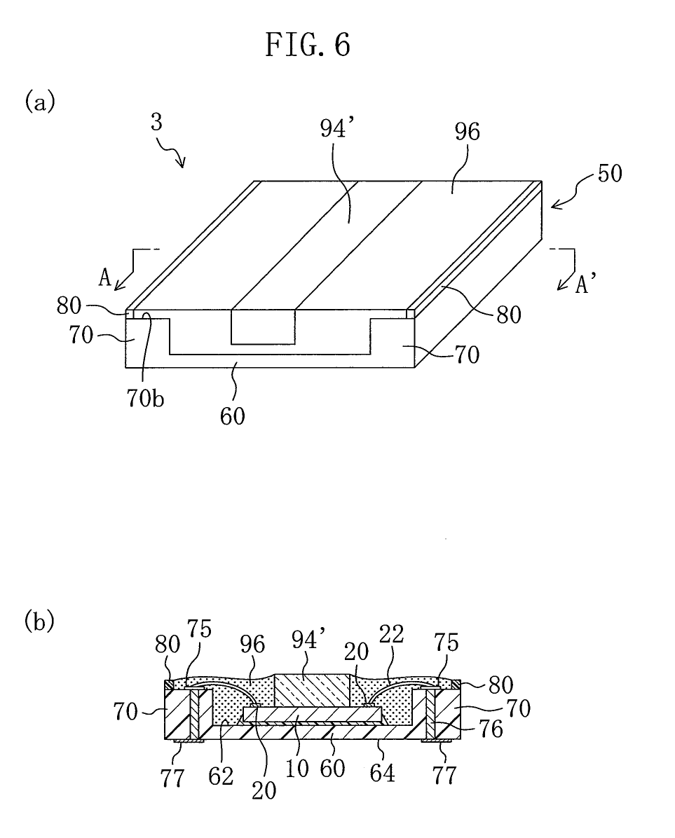

As illustrated in FIG. 6, a transparent member 94′ of a semiconductor device 3 according to this embodiment extends out from the upper surface of a semiconductor element 10, and is exposed, together with a base 60, ribs 70, 70, and an encapsulating resin 96, at a pair of side surfaces of the semiconductor device 3 perpendicular to the direction in which the ribs 70, 70 extend.

In the fabrication of the semiconductor device 2 of the second embodiment, the transparent members 94 are respectively bonded to the upper surfaces of the semiconductor elements 10. On the other hand, in this embodiment, a single long transparent member 94′ is placed on the upper surfaces of a plurality of semiconductor elements 10. Specifically, between a process step shown in FIG. 5(c) and a process step shown in FIG. 5(d), a transparent member 94′ having substantially the same length as that of each of trenches 55 is prepared, and is placed on a plurality of semiconductor elements 10, 10, . . . fixed to the bottom surface of each of the trenches 55. The cross-sectional view thereof is the same as that in FIG. 5 for the second embodiment. Lastly, in separating individual semiconductor devices 3, the transparent member 94′ is cut together with the base 60, the ribs 70, 70, and the encapsulating resin 96, and is exposed at the cutting plane.

In this embodiment, in addition to the advantages of the second embodiment, the process step of placing the transparent member 94′ on the semiconductor elements 10 is simplified, thus facilitating fabrication.

Spacers 80, 80 may be removed as in a semiconductor device 3′ illustrated in FIG. 8.

### EMBODIMENT 4

A semiconductor device according to a fourth embodiment differs from the semiconductor device 2 of the second embodiment only in that no spacers 80, 80 are provided and an encapsulating resin 96 occupies the space where the spacers 80, 80 are present in the semiconductor device 2. Thus, different aspects are described.

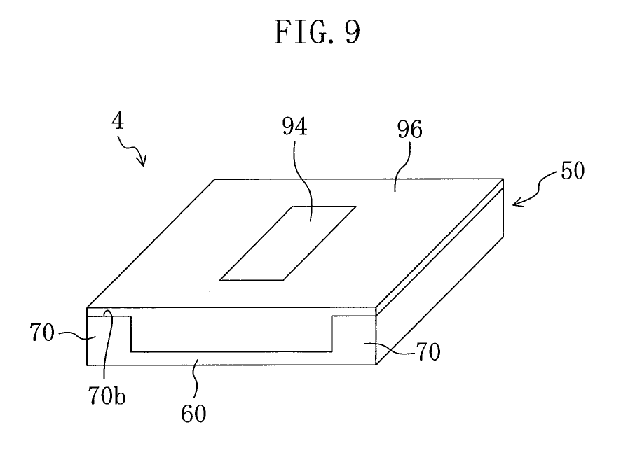

As illustrated in FIG. 9, a semiconductor device 4 according to this embodiment has a structure in which the spacers 80, 80 of the semiconductor device 2 of the second embodiment are removed and the space where the spacers 80, 80 were present is filled with the encapsulating resin 96.

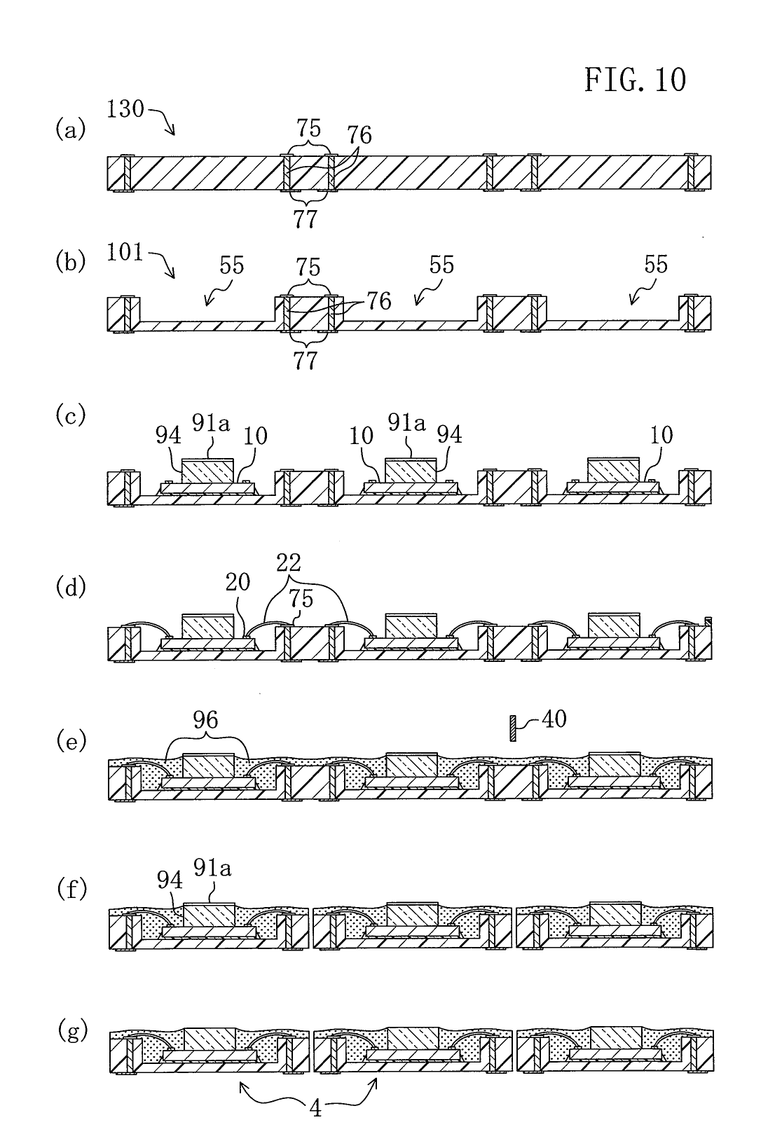

In process steps for fabricating the semiconductor device 4 of this embodiment, as illustrated in FIG. 10, a package-assembled board 101 is obtained by removing the spacers 80′ from the package-assembled board 100 of the second embodiment (see, FIG. 10(b)).

A plurality of semiconductor elements 10 are sequentially placed on, and fixed to, the bottom surfaces of trenches 55, 55, . . . of this package-assembled board 101 along the direction in which the trenches 55, 55, . . . extend. Then, transparent members 94 are respectively placed on the light-receiving surfaces of the semiconductor elements 10 mounted in one of the trenches 55, and are fixed with a transparent adhesive. At this time, protective sheets 91 a are provided on the upper surfaces of the transparent members 94. In this manner, the state illustrated in FIG. 10(c) is obtained.

Then, electrode pads 20 of the semiconductor elements 10 are wire bonded to connection electrodes 75. In this manner, as illustrated in FIG. 10(d), the electrode pads 20 and the connection electrodes 75 are connected to each other by metal wires 22.

Thereafter, the trenches 55 are filled with an encapsulating resin 96. This filling may be achieved by potting or injection molding. At this time, the entire upper surfaces of the transparent members 94 are covered with the protective sheets 91a, thus ensuring that the upper surfaces of the transparent members 94 are not covered with the encapsulating resin 96 and are exposed. FIG. 10(e) shows a state in which the encapsulating resin 96 fills the trenches, and is cured.

Subsequently, the board is cut with a dicing saw 40 in such a manner that two lines of the connection electrodes 75 between adjacent two of the trenches 55, 55 are separated from each other. The state after the separation is shown in FIG. 10(f). In this manner, side wall surfaces including those of the encapsulating resin 96 are made flush with one another.

Then, the protective sheets 91 a are peeled off from the transparent members 94. Thereafter, adjacent ones of the semiconductor elements 10 arranged perpendicularly to the direction along which the trenches 55 extend are separated from each other. In this manner, individual semiconductor devices 4 are obtained. This state is illustrated in FIG. 10(h).

The fabrication method of this embodiment has the same advantages as those of the fabrication method of the second embodiment. In addition, the absence of spacers 80′ simplifies the fabrication process accordingly.

### EMBODIMENT 5

A semiconductor device according to a fifth embodiment differs from the semiconductor device 3 of the third embodiment in that no spacers 80, 80 are provided and an encapsulating resin 96 occupies the space where the spacers 80, 80 are present in the semiconductor device 3. That is, in this embodiment, the transparent member 94′ of the third embodiment is employed as the transparent member of the fourth embodiment.

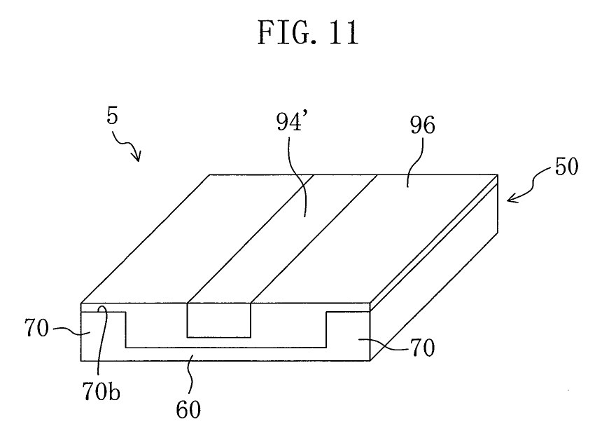

As illustrated in FIG. 11, in a semiconductor device 5 according to this embodiment, a base 60, ribs 70, 70, a transparent member 94′, and an encapsulating resin 96 are exposed at a pair of side surfaces of the semiconductor device 5, as in the third embodiment. In addition, as in the fourth embodiment, the encapsulating resin 96 also covers external edges of the ribs 70, 70, and no spacers are provided.

Fabrication of the semiconductor device 5 of this embodiment differs from that of the semiconductor device 4 of the fourth embodiment only in that a single long transparent member 94′ replaces the transparent members 94 and is placed on, and bonded to, a plurality of semiconductor elements 10, 10, . . . in the process step of fabricating the semiconductor device 4 of the fourth embodiment shown in FIG. 10(c), and that the transparent member 94′ is cut, together with the ribs 70, 70, the encapsulating resin 96, and other components, to form individual semiconductor devices 5 in the process step shown in FIG. 10(g). The other aspects are the same as those of the fabrication of fourth embodiment.

This embodiment provides the same advantages as those of the third and fourth embodiments.

### EMBODIMENT 6

### Semiconductor Device

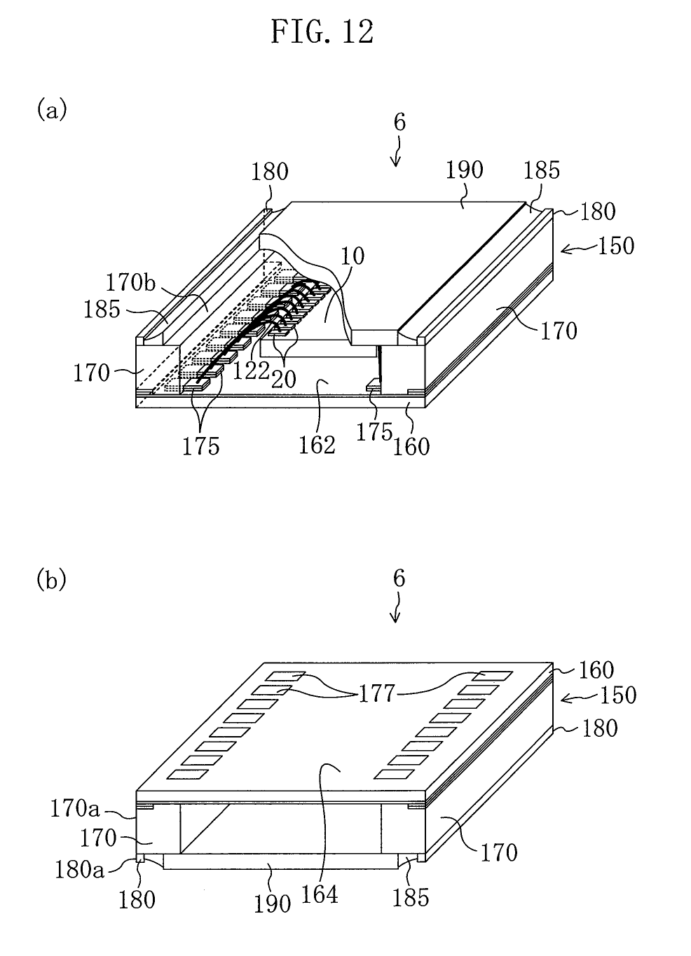

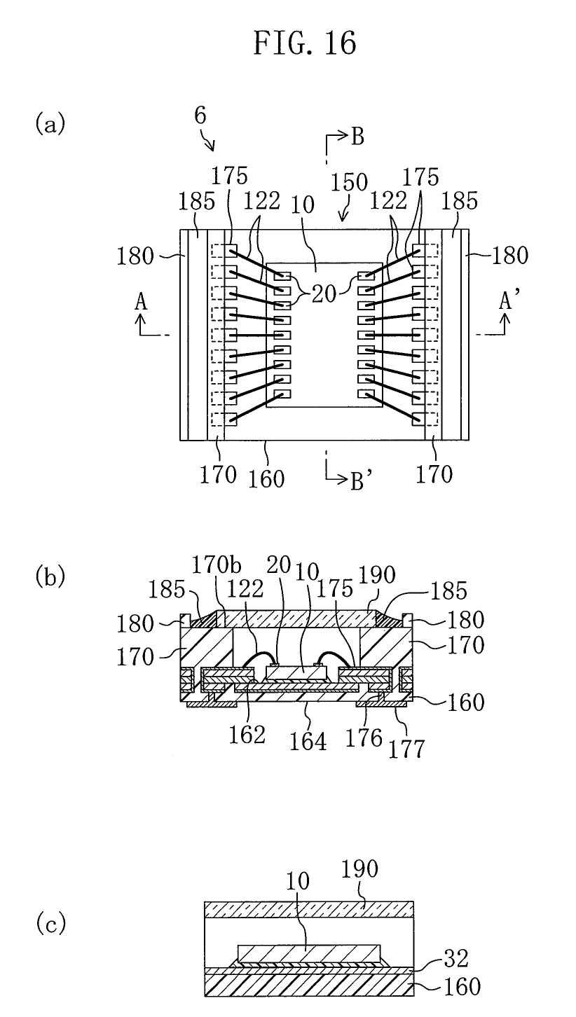

A semiconductor device fabricated with a fabrication method according to a sixth embodiment differs from those of the first through fifth embodiments in a package, but employs the same semiconductor element 10 as those in the first through fifth embodiments. Thus, description is given mainly on a package 150 with reference to FIGS. 12 and 16. It should be noted that a transparent lid 190 is actually placed on the package 150, but the lid 190 is removed and is not shown in FIG. 16(a) for convenience of description. In addition, copper plating, which will be described later, is thin, and thus is not shown, either. In the drawings for describing the following embodiments, copper plating is not shown as necessary.

The package 150 of this embodiment includes: a rectangular base 160; two ribs 170, 170 projecting upward from the base 160 and respectively extending along a pair of opposite sides of the rectangle; and spacers 180, 180 respectively provided at external edges of the rib upper surfaces 170b. The ribs 170, 170 are respectively provided only on a pair of opposite external edges of a rectangular mounting surface 162 of the base 160 on which the semiconductor element 10 is mounted. Each of the ribs 170, 170 is in the shape of a rectangular solid extending along an associated one of the external edges of the mounting surface 162. The phrase “the ribs 170, 170 are provided only on a pair of external edges of the mounting surface 162” means that the ribs 170, 170 are provided on the above-mentioned pair of external edges but no ribs 170, 170 are provided on another pair of opposite external edges of the mounting surface 162 and a center portion and its periphery of the mounting surface 162.

On the mounting surface 162, a plurality of connection electrodes 175, 175, . . . are aligned between the mounted semiconductor element 10 and each of the ribs 170. Each of the connection electrodes 175 extends to a portion under an associated one of the ribs 170, and is partially hidden under the rib 170. The connection electrodes 175 are connected to buried electrodes 176, 176, . . . provided in the base 160. The buried electrodes 176, 176, . . . refer to the entire parts of a conductor buried in the base 160. A plurality of external-connection portions 177, 177, . . . are provided on a non-mounting surface 164 of the base 160 opposite the mounting surface 162, and are connected to the buried electrodes 176, 176, . . . . That is, the connection electrodes 175, 175, . . . are electrically connected to the external-connection portions 177, 177, . . . via the buried electrodes 176, 176, . . . .

The semiconductor element 10 is mounted on the package 150 in such a manner that the electrode pads 20, 20, . . . are arranged in lines substantially in parallel with the direction along which the ribs 170, 170 extend and that the electrode pads 20, 20, . . . are connected to the connection electrodes 175, 175, . . . by metal wires 122, 122, . . . .

The spacers 180, 180 are located farthest from the semiconductor element 10 on the rib upper surfaces 170b, and extend along the direction in which the ribs 170, 170 extend. External edge portions of a rectangular lid 190 are respectively placed on the rib upper surfaces 170b at locations away from the spacers 180, 180, and are fixed with an adhesive 185. The adhesive 185 is sandwiched between the lower surfaces of the external edge portions of the lid 190 and the rib upper surfaces 170b, and is also sandwiched between the spacer 180 and side surfaces of the lid 190. The portions of the adhesive 185 located between the rib upper surfaces 170b and the lid 190 are thin, and thus are not shown in FIGS. 12(a), 12(b), and 16(b). In the same manner, these portions are not shown in cross-sectional views for the seventh and subsequent embodiments.

Since the adhesive 185 is sandwiched between the spacers 180 and the side surfaces of the lid 190 in this embodiment, the lid 190 is more firmly fixed to the ribs 170 than in a configuration where the adhesive 185 is sandwiched only between the lower surfaces of the external edge portions of the lid 190 and the rib upper surfaces 170b. In particular, in this embodiment, portions of the adhesive 185 sandwiched between the spacers 180 and the side surfaces of the lid 190 form fillets at the corners formed by the side surfaces of the lid 190 and the rib upper surfaces 170b, thus more firmly fixing the lid 190 to the ribs 170 even with a small amount of the adhesive 185.

In addition, a rib external side wall surface 170a and a spacer external side wall surface 180a are flush with each other at each side wall surface of the semiconductor device 6. This structure can reduce the length of the side of the semiconductor device 6 between the ribs 170, 170, thus contributing to miniaturization. Moreover, the extension of the adhesive 185 is blocked by the spacers 180, and thus the adhesive 185 does not extend out from the side wall surfaces of the semiconductor device 6. The “external side wall surfaces” herein refer to the side wall surfaces of the ribs 170, 170 and the spacers 180, 180 opposite the side wall surfaces thereof facing the semiconductor element 10.

In this embodiment, no ribs are provided on a pair of opposite external edges of the base 160 different from the pair of opposite external edges thereof on which the ribs 170, 170 are provided. Thus, the distance between the pair of opposite external edges on which no ribs are provided is determined according to the size of the semiconductor element 10 and the area necessary for arranging the connection electrodes 175, 175, . . . . That is, the distance between the pair of opposite external edges with no ribs can be minimized in a package on which the semiconductor element 10 is mounted.

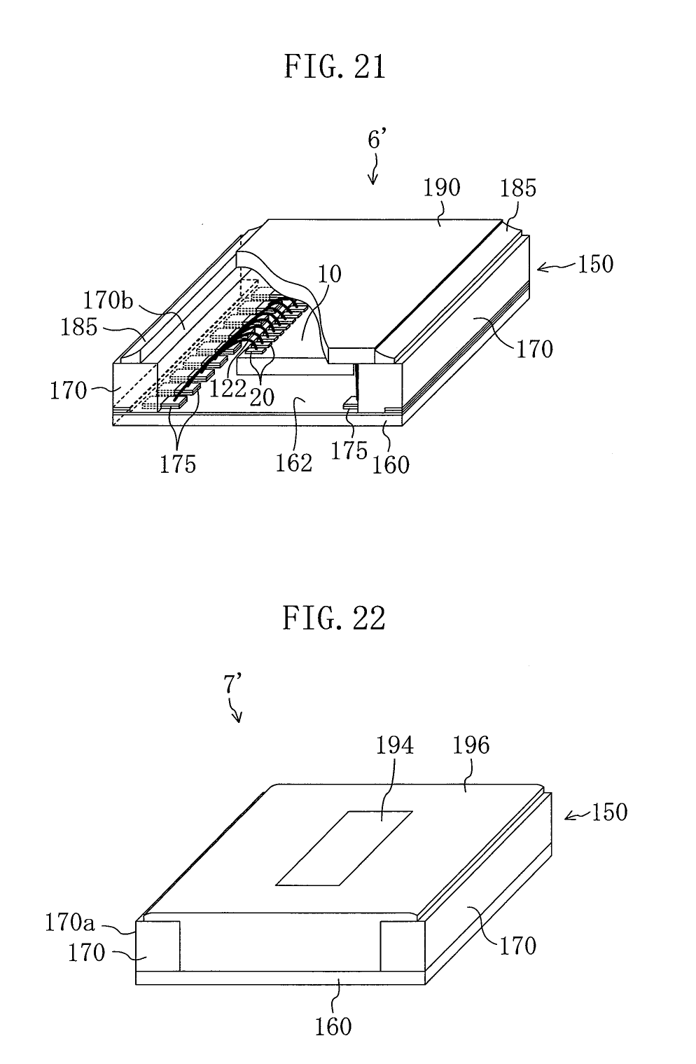

The spacers 180, 180 may be removed, as in a semiconductor device 6′ illustrated in FIG. 21.

### Method for Fabricating Semiconductor Device

A method for fabricating a semiconductor device 6 according to this embodiment is now described.

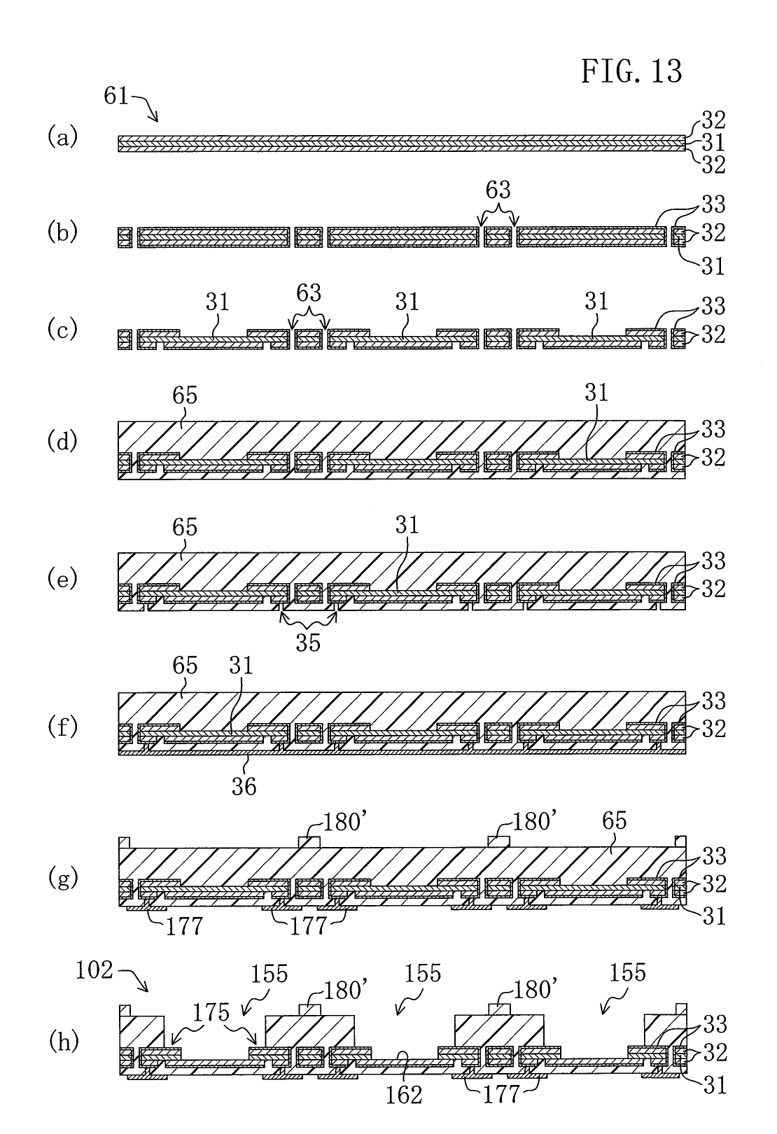

First, as illustrated in FIG. 13, a package-assembled board 102 is prepared. In the package-assembled board 102, a plurality of packages 150 described above are arranged, and rib external side wall surfaces 170a of adjacent ones of the packages 150 are united. Along the direction in which the ribs extend, a plurality of packages 150 are also arranged and united.

As illustrated in FIG. 13(a), this package-assembled board 102 is formed based on a double-sided copper-plated board 61 obtained by attaching copper foil 32, 32 to both surfaces of an insulating base material 31 in the shape of a flat plate. Through holes 63 are formed in given portions of this double-sided copper-plated board 61, and the inner walls of the through holes 63 and the copper foil 32 are coated with copper plating 33 (see, FIG. 13(b)).

Then, a resist is provided by patterning in such a manner that portions of the copper foil 32 and the copper plating 33 are to be connection electrodes 175 and parts of buried electrodes 176, respectively. With this resist, etching is performed, thereby removing portions of the copper foil 32 and the copper plating 33 on which semiconductor elements 10 are to be mounted (see, FIG. 13(c)).

Thereafter, the entire board is soaked in a resin 65, and this resin 65 is cured to be in a plate shape. At this time, the thickness of the resin 65 is large on the upper surface of the double-sided copper-plated board 61, and is small on the lower surface of the double-sided copper-plated board 61 (see, FIG. 13(d)).

Subsequently, in order to connect external-connection portions 177 and buried electrodes 176 to each other, openings 35 are formed in given portions of the lower surface of the resin 65 to reach the copper foil 32 on the lower surface of the insulating base material 31, actually to reach the copper plating 33 on the surface of this copper foil 32 (see, FIG. 13(e)). Thereafter, the entire lower surface of the board is coated with plating 36. At this time, the openings 35 are also filled with the plating 36.

Then, after a resist has been applied on the plating 36 at the lower surface of the board, patterning is performed, and then the plating 36 is etched, thereby forming external-connection portions 177, 177, . . . . Then, spacers 180′, 180′, . . . in the shape of rods are attached to the resin 65 at the upper surface of the board. The spacers 180′, 180′, . . . are located on portions to be ribs 170, 170, . . . (see, FIG. 13(g)).

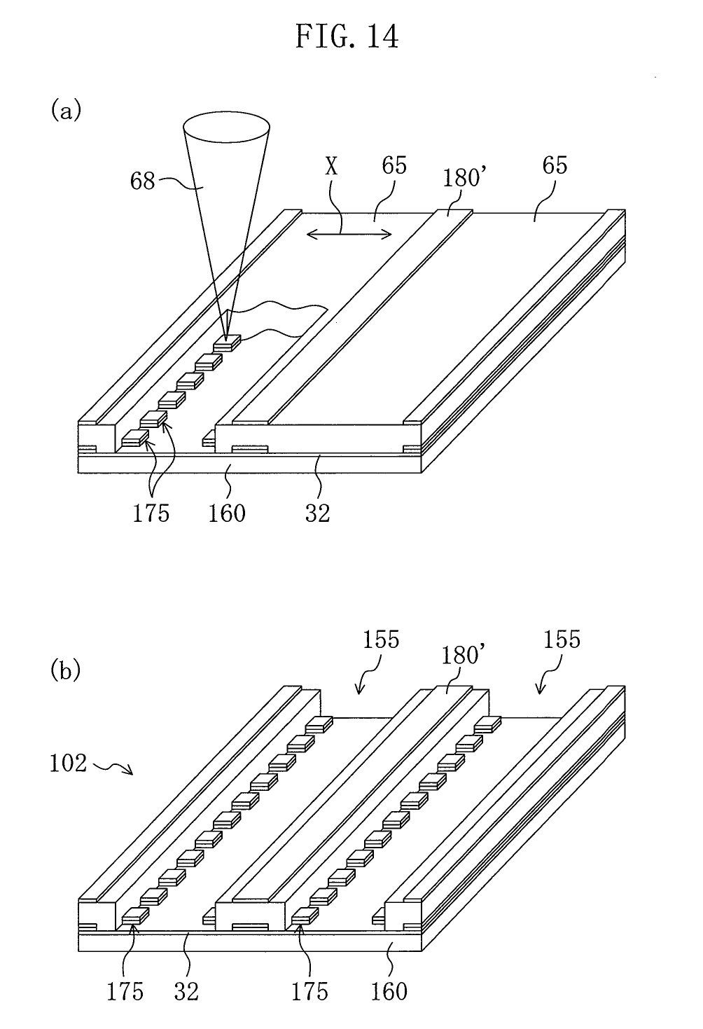

Thereafter, as illustrated in FIG. 14(a), the resin 65 at the upper surface of the board is irradiated with laser light 68, thereby removing parts of the resin 65 and the insulating base material 31 to expose connection electrodes 175, 175, . . . . The removal of the resin 65 and the insulating base material 31 is because direct irradiation of the resin 65 and the insulating base material 31 with the laser light 68 induces a high-temperature condition to cause sublimation of the resin 65 and the insulating base material 31. On the other hand, the laser light 68 does not have enough power to cause sublimation of copper, and thus even when the copper foil 32 and the copper plating 33 are irradiated with the laser light 68, no sublimation of their underlying resin 65 and the insulating base material 31 occurs. In FIG. 14, the copper plating 33 is not shown.

The laser light 68 is applied to a portion having a width X between adjacent spacers 180′, 180′. The laser light 68 moves in the direction along which the trenches 155 extend, while scanning the portion having the width X. Accordingly, portions to be ribs 170, 170 are not irradiated with the laser light 68, and remain unchanged. In this manner, as illustrated in FIGS. 13(h) and 14(b), trenches 155, 155, . . . are formed, thereby obtaining a package-assembled board 102. In the package-assembled board 102, the copper foil 32 at the lower surface of the board is exposed at portions on which semiconductor elements 10 are to be mounted, and the connection electrodes 175, 175, . . . have a structure in which the insulating base material 31 and the upper copper foil 32 are stacked in this order on the lower copper foil 32.

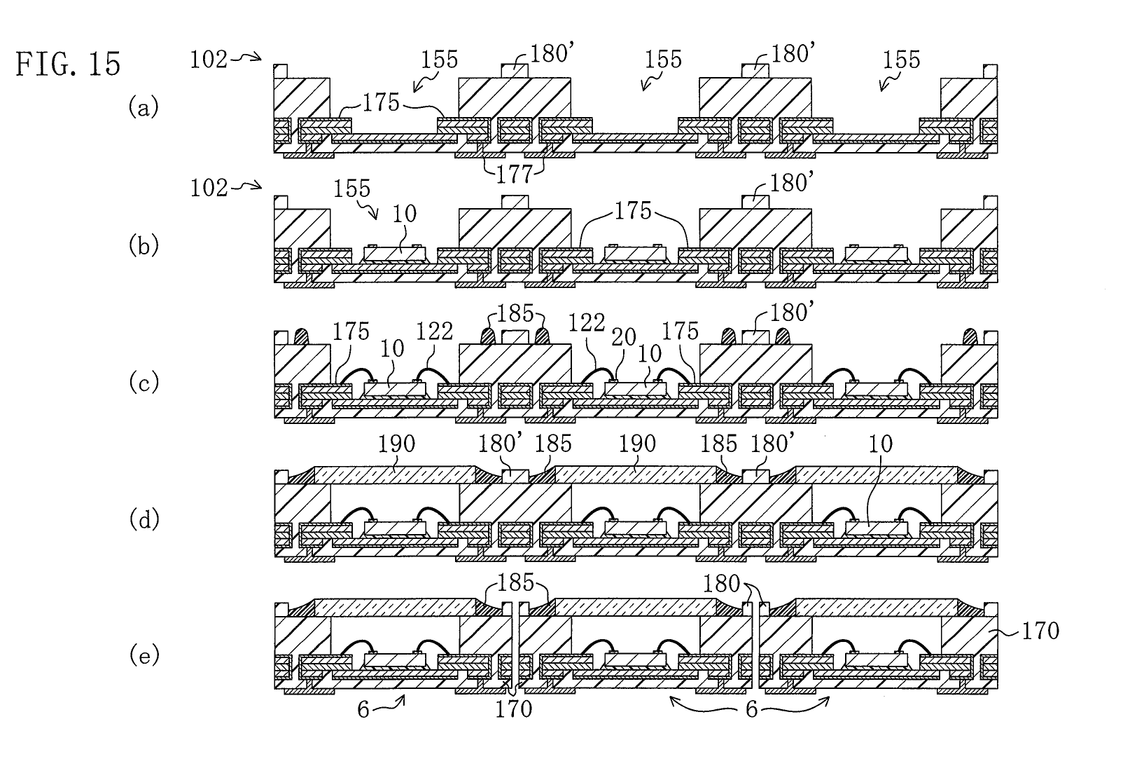

Now, process steps of fabricating a semiconductor device 6 by using this package-assembled board 102 is described with reference to FIG. 15.

First, as illustrated in FIG. 15(a), a package-assembled board 102 is prepared.

The package-assembled board 102 actually further extends in the vertical and horizontal direction in FIG. 15(a), but the extending portions are not shown. Thereafter, a plurality of semiconductor elements 10 are mounted on, and fixed to, each of the bottom surfaces of the trenches 155, 155, 155 along the direction in which the trenches 155, 155, 155 extend. This state is illustrated in FIG. 15(b).

Next, electrode pads 20 of the semiconductor elements 10 are wire bonded to the connection electrodes 175. Subsequently, an adhesive 185 is continuously applied, along the trenches 155, onto portions of the upper surfaces of portions to be the ribs 170 located between the spacers 180′ and the trenches 155. In this manner, as illustrated in FIG. 15(c), the electrode pads 20 and the connection electrodes 175 are connected to each other by metal wires 122, and the adhesive 185 is located on the upper surfaces of the portions to be the ribs 170.

The continuous application of the adhesive 185 described above means that the adhesive 185 is applied in a line along the spacers 180′ without interruption at portions corresponding to boundaries between adjacent semiconductor elements 10 disposed along the trenches 155.

Thereafter, transparent lids 190 for the respective semiconductor elements 10 are placed on the package-assembled board 102 in such a manner that external edge portions of the lids 190 are located on the adhesive 185. The lids 190 cover the respective semiconductor elements 10. Then, the adhesive 185 is hardened, thereby bonding and fixing the lids 190. This state is shown in FIG. 15(d). At this time, each of the external edges of the lids 190 is located on approximately a half of the applied adhesive 185, and thus the adhesive 185 is not only located between the lower surfaces of the lids 190 and the upper surfaces of the portions to be the ribs 170 but also adheres to the side surfaces of the lids 190, and is extruded toward the spacers 180′. However, the spacers 180′ block the extrusion of the adhesive 185 and prevent the adhesive 185 from extending out to the adjacent package regions. At the same time, the adhesive 185 forms fillets which adhere to the side surfaces of the lids 190 and become thinner toward the spacers 180′.

Subsequently, a middle portion of each of the spacers 180′ between adjacent two of the trenches 155, 155 is cut into two with a dicing saw 40. In this manner, the side wall surfaces become flush with one another. Then, adjacent ones of the semiconductor elements 10 disposed perpendicularly to the direction along which the trenches 155 extend are separated from each other. The state after the separation is shown in FIG. 15(e). In this manner, individual semiconductor devices 6 are obtained.

The above-described method for fabricating semiconductor devices 6 is merely an example, and the fabrication method of this embodiment is not limited to this example. The lids 190 may be placed after the separation of the adjacent trenches 155, 155. The spacers 180′ does not need to be formed by being attached to the resin 65, and may be formed of the resin 65 simultaneously with application of the resin 65 onto both surfaces of the double-sided copper-plated board 61. Alternatively, a plurality of trenches 155, 155, . . . may be formed at a time by using a plurality of laser-light emitting devices.

In the fabrication method of this embodiment, the size of the package-assembled board 102 may be arbitrarily selected, and it is possible to easily fabricate, in a short period of time, even a large-size package-assembled board 102 on which a large number of semiconductor elements 10 can be mounted. As a result, small-size semiconductor devices 6 can be fabricated at low cost. Formation of a plurality of trenches 155, 155, . . . at a time enables efficient fabrication of the package-assembled board 102 in a short period of time.

### EMBODIMENT 7

### Semiconductor Device

A semiconductor device according to a seventh embodiment differs from the semiconductor device 6 of the sixth embodiment in that a plate-like transparent member replaces the transparent flat lid and is placed on a semiconductor element, and that a trench in the package is filled with an encapsulating resin in such a manner that side surfaces of the transparent member and metal wires are buried in the resin. Now, this embodiment, particularly aspects thereof different from those of the sixth embodiment, is described.

The same aspects as those of the sixth embodiment may be omitted in the following description.

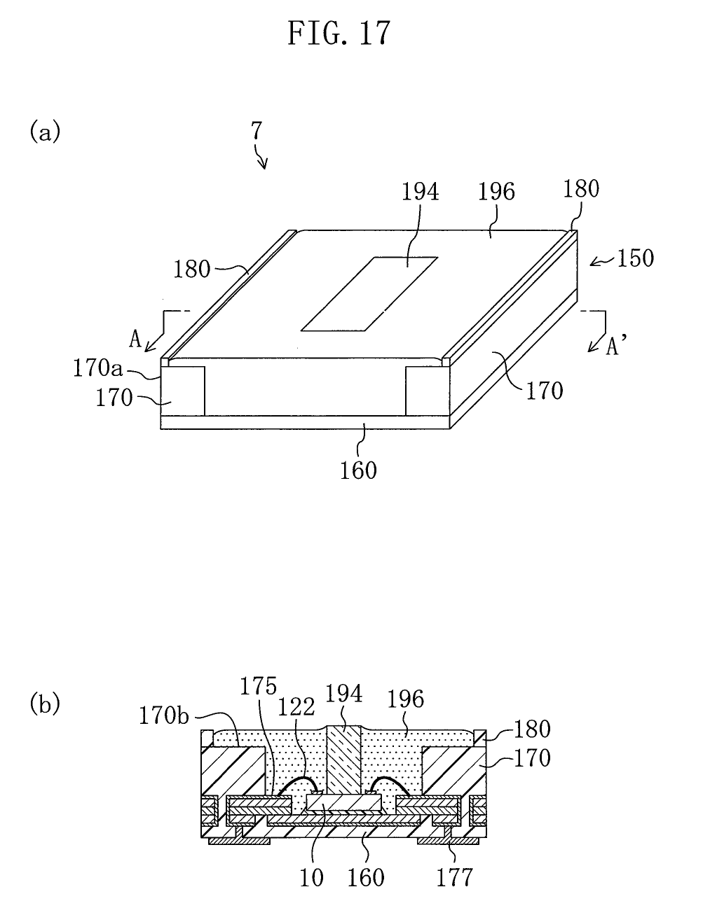

FIGS. 17(a) and 17(b) illustrate a semiconductor device 7 according to this embodiment. In this embodiment, a package 150, a semiconductor element 10, spacers 180, 180, ribs 170, 170, and metal wires 122 are the same as those in the sixth embodiment, and a configuration for connecting connection electrodes 175 to external-connection portions 177 and a configuration for connecting a semiconductor element 10 to the connection electrodes 175 are also the same as those in the sixth embodiment. The semiconductor element 10 mounted on the package 150 is connected to the connection electrodes 175 by the metal wires 122. A plate-like transparent member 194 is placed to cover the light-receiving surface of the semiconductor element 10 with a transparent adhesive interposed between the semiconductor element 10 and the transparent member 194. The transparent member 194 is a plate-like member having a rectangular upper surface and made of glass, and adheres to the semiconductor element 10.

In addition, components provided in a trench (a recess) of the package 150 except for the upper surface of the transparent member 194 and the upper surfaces of the spacers 180, 180 are encapsulated with the encapsulating resin 196. Specifically, side surfaces of the transparent member 194, the upper surfaces of the ribs 170, 170, and the metal wires 122, for example, are buried in the encapsulating resin 196. At a pair of side surfaces of the semiconductor device 7 perpendicular to the direction in which the ribs 170, 170 extend, the base 160, the ribs 170, 170, and the encapsulating resin 196 are exposed.

When viewed from above the semiconductor device 7 of this embodiment, only the upper surface of the transparent member 194 and the upper surfaces of the spacers 180, 180 are exposed, and the other components are covered with the encapsulating resin 196. Accordingly, no dirt and dust accumulate on the light-receiving surface of the semiconductor element 10, electrode pads 20, the connection electrodes 175, and the metal wires 122, thus avoiding failures such as short circuits caused by dirt and dust. The encapsulating resin is preferably one of a thermosetting epoxy resin, a filler-added resin containing, for example, SiO₂, and a resin which contains a dye and exhibits a light-blocking property, for example.

The encapsulating resin 196 is a high-viscosity liquid when filling the trench of the package 150, and is then cured. At the side wall surfaces of the semiconductor device 7 except for rib external side wall surfaces 170a, the encapsulating resin 196 is flush with the end surfaces of the ribs 170, 170. The metal wires 122 are completely buried in the encapsulating resin 196, and thus portions of the metal wires 122 in contact with the electrode pads 20 and with the connection electrodes 175 are fixed, thus enhancing connection reliability. In addition, since the upper surface of the transparent member 194 is exposed and the side surfaces of the transparent member 194 are buried in the encapsulating resin 196, only light that has passed through the upper surface of the transparent member 194 reaches the light-receiving surface of the semiconductor element 10. Even when light enters the side surfaces of the transparent member 194, such light does not reach the light-receiving surface. Consequently, stray light (i.e., diffuse reflection of light) can be eliminated, and thus optical properties can be enhanced.

With respect to the height (i.e., distance) from a mounting surface 162 of a base 160, the height of the upper surface of the transparent member 194 is larger than that of the upper surfaces of the spacers 180, 180. Accordingly, in placing the semiconductor device 7 in an optical pickup module, the upper surface of the transparent member 194 that is parallel to the light-receiving surface of the semiconductor element 10 and has a large area can be easily used as a reference surface for the placement. In addition, accuracy in the placement in the optical pickup module can be easily enhanced. Further, the placement can be easily performed for a short period of time.

### Method for Fabricating Semiconductor Device

A method for fabricating a semiconductor device 7 according to this embodiment is now described. Description of process steps already described in the first embodiment is omitted or simplified.

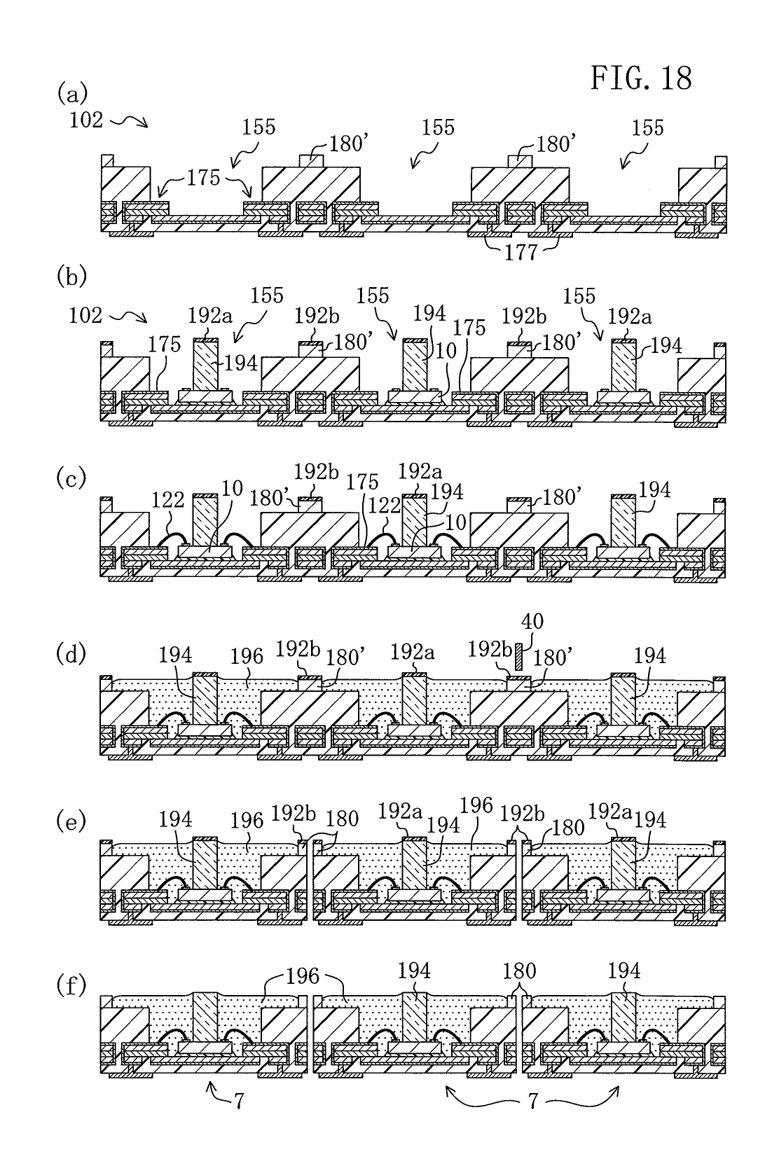

First, a package-assembled board 102 illustrated in FIG. 18(a) is prepared. This package-assembled board 102 is identical to that used in the sixth embodiment.

Next, a plurality of semiconductor elements 10 are sequentially placed on, and fixed to, the bottom surfaces of trenches 155, 155, . . . along the direction in which the trenches 155, 155, . . . extend. Then, transparent members 194 are placed on the light-receiving surfaces of the semiconductor elements 10, and are fixed with a transparent adhesive. At this time, protective sheets 192a are provided on the upper surfaces of the transparent members 194. Protective sheets 192b are then provided on the upper surfaces of the spacers 180′. In this manner, the state illustrated in FIG. 18(b) is obtained.

Then, electrode pads 20 of the semiconductor elements 10 are wire bonded to connection electrodes 175. In this manner, as illustrated in FIG. 18(c), the electrode pads 20 are connected to the connection electrodes 175 by metal wires 122.

Thereafter, the trenches 155 are filled with an encapsulating resin 196. This filling may be achieved by potting or injection molding. At this time, the entire upper surfaces of the transparent members 194 and the upper surfaces of the spacers 180′ are covered with the protective sheets 192a, 192b. This structure ensures that the upper surfaces of the transparent members 194 and the upper surfaces of the spacers 180′ are not covered with the encapsulating resin 196 and are exposed. FIG. 18(d) shows a state in which the encapsulating resin 196 fills the trenches, and is cured.

Subsequently, the board is cut with a dicing saw 40 at middle portions of the spacers 180′ each located between adjacent two of the trenches 155, 155. The state after the cutting is shown in FIG. 18(e). In this manner, side wall surfaces are made flush with one another.

Then, the protective sheets 192a and 192b are peeled off from the transparent members 194 and the spacers 180′, thereby obtaining a state illustrated in FIG. 18(f). Thereafter, adjacent ones of the semiconductor elements 10 disposed perpendicularly to the direction along which the trenches 155 extend are separated from each other. In this manner, individual semiconductor devices 7 are obtained. It should be noted that because of compression of the encapsulating resin 196 during curing, the upper surface of the encapsulating resin 196 is located several micrometers below the upper surfaces of the transparent members 194 and the upper surfaces of the spacers 180.

As the semiconductor device 6 of the sixth embodiment, the semiconductor device 7 of this embodiment can also be made smaller in size than conventional semiconductor devices.

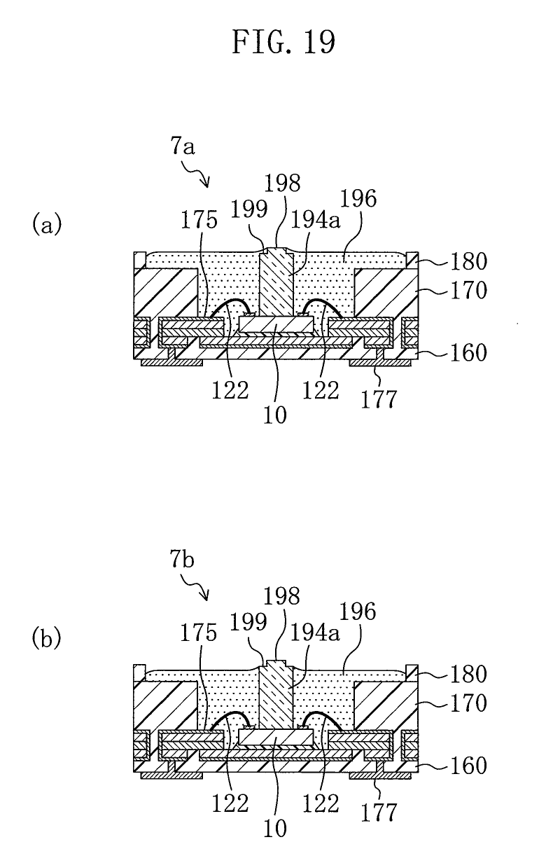

Further, the transparent members 194 may be modified to form semiconductor devices 7a, 7b including steps on external edge portions of upper surfaces, as illustrated in FIGS. 19(a) and 19(b). In FIG. 19(a), the upper surface of a transparent member 194a is stepped to have: a top surface 198 located in a middle portion of this upper surface and corresponding to the shape and size of the optical functional surface of a semiconductor element 10; and stepped surfaces 199 located below the top surface 198 at a distance corresponding to the steps. An encapsulating resin 196 covers the stepped surfaces 199, but does not cover the top surface 198. The presence of the stepped surfaces 199 in this manner ensures that the top surface 198 is not covered with the encapsulating resin 196, resulting in ensuring entering of necessary light into the optical functional surface of the semiconductor element 10, or resulting in efficient emission of light from the optical functional surface.

Alternatively, as illustrated in FIG. 19(b), none of stepped surfaces 199 and a top surface 198 of a semiconductor device 7b may be covered with an encapsulating resin 196.

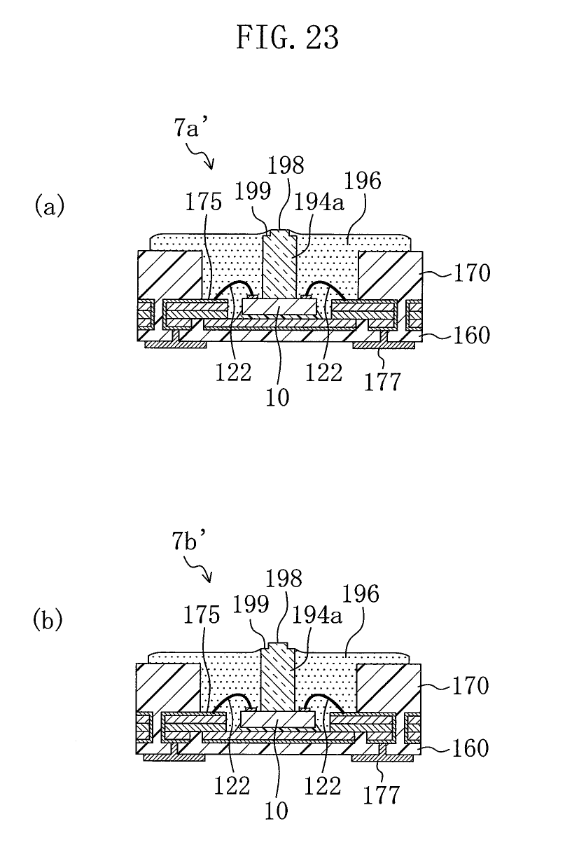

The spacers 180, 180 may be removed, as in semiconductor devices 6′, 7a′, and 7b′ illustrated in FIGS. 22 and 23.

### EMBODIMENT 8

A semiconductor device according to an eighth embodiment differs from the semiconductor device 7 of the seventh embodiment in a transparent member, and thus different aspects thereof are described. The relationship between the seventh and eighth embodiments is the same as that between the second and third embodiments.

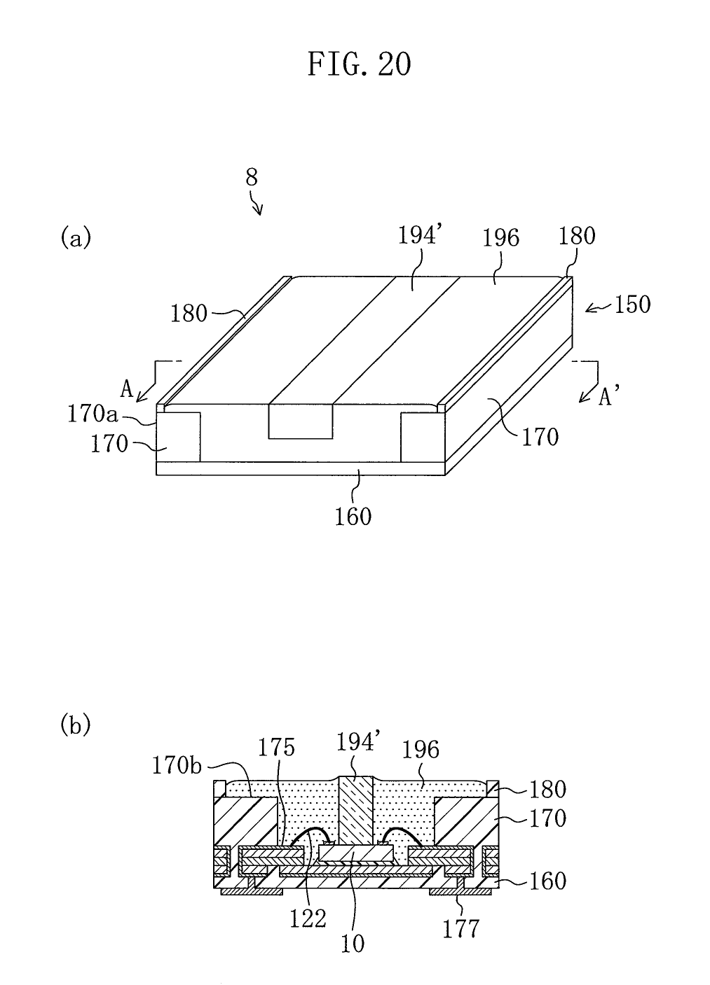

As illustrated in FIG. 20, a transparent member 194′ of a semiconductor device 8 according to this embodiment extends out from the upper surface of a semiconductor element 10, and is exposed, together with a base 160, ribs 170, 170, and an encapsulating resin 196, at a pair of side surfaces of the semiconductor device 8 perpendicular to the direction in which the ribs 170, 170 extend.

In the fabrication of the semiconductor device 7 of the seventh embodiment, the transparent members 194 are respectively bonded to the upper surfaces of the semiconductor elements 10. On the other hand, in this embodiment, a single long transparent member 194′ is placed on the upper surfaces of a plurality of semiconductor elements 10. Specifically, between a process step shown in FIG. 18(a) and a process step shown in FIG. 18(b), a transparent member 194′ having a substantially the same length as that of each of trenches 155 is prepared, and is placed on a plurality of semiconductor elements 10, 10, . . . fixed to the bottom surface of each of the trenches 155. The cross-sectional view thereof is the same as that in FIG. 18 for the seventh embodiment. Lastly, in separating individual semiconductor devices 8, the transparent member 194′ is cut together with the base 160, the ribs 170, 170, and the encapsulating resin 196, and is exposed at the cutting plane.

In addition to the advantages of the seventh embodiment, the process step of placing the transparent member 194′ on the semiconductor elements 10 is simplified, thus facilitating fabrication.

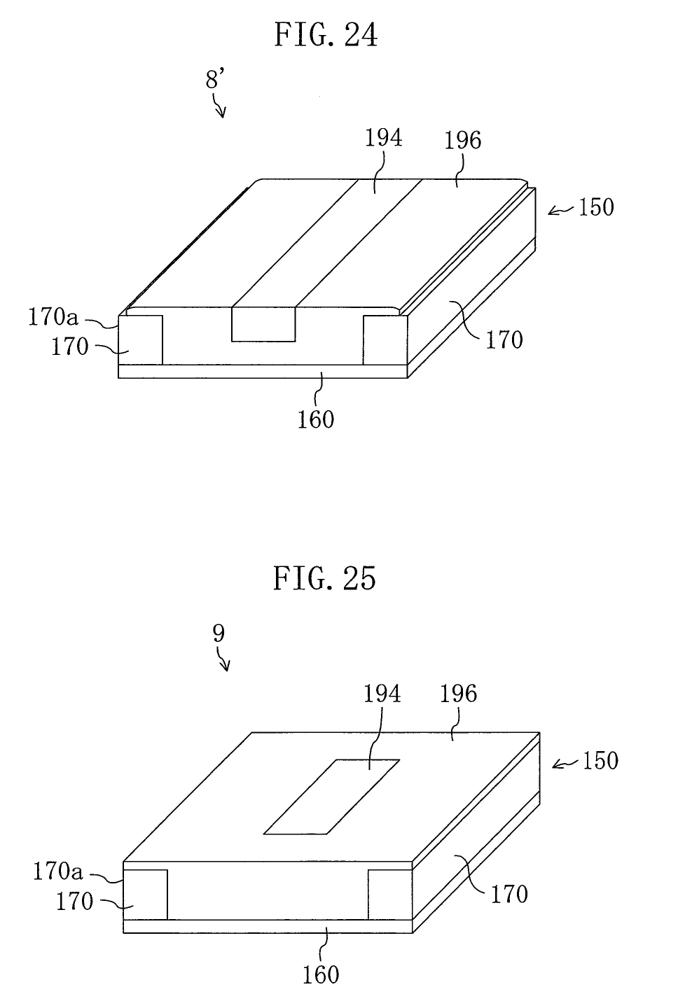

The spacers 180, 180 may be removed as in a semiconductor device 8′ illustrated in FIG. 24.

### EMBODIMENT 9

A semiconductor device according to a ninth embodiment differs from the semiconductor device 7 of the seventh embodiment in that the no spacers 180, 180 are provided and an encapsulating resin 196 occupies the space where the spacers 180, 180 are present in the semiconductor device 7. Thus, different aspects are described. The relationship between the seventh and ninth embodiments is the same as that between the second and fourth embodiments.

As illustrated in FIG. 25, a semiconductor device 9 according to this embodiment has a structure in which the spacers 180, 180 of the semiconductor device 7 of the seventh embodiment are removed and the space where the spacers 180, 180 were present is filled with an encapsulating resin 196.

The semiconductor device 9 of this embodiment is fabricated by using the package-assembled board 102 of the sixth embodiment, instead of the package-assembled board 101, in the fabrication of the fourth embodiment. Thus, description of fabrication is now omitted.

The fabrication method of this embodiment has the same advantages as those of the fabrication method of the seventh embodiment. In addition, the absence of spacers 80′ in this embodiment simplifies the fabrication process accordingly.

### EMBODIMENT 10

A semiconductor device according to a tenth embodiment differs from the semiconductor device 8 of the eighth embodiment in that no spacers 180, 180 are provided and an encapsulating resin 196 occupies the space where the spacers 180, 180 are present in the semiconductor device 8. That is, the transparent member 194′ of the eighth embodiment is employed as a transparent member in the ninth embodiment.

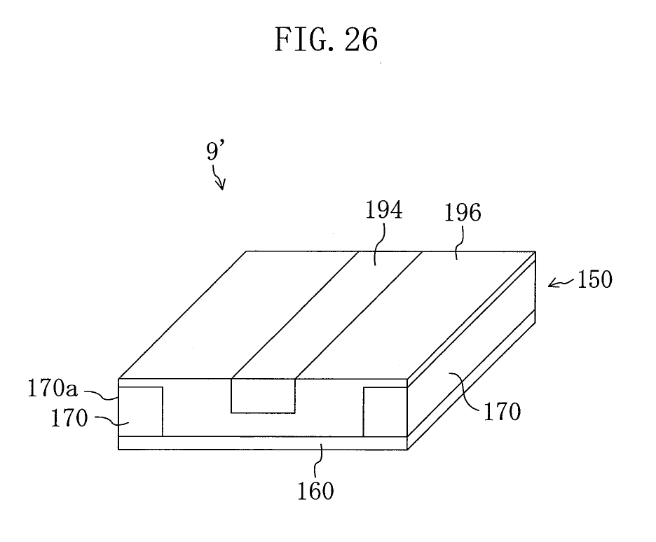

As illustrated in FIG. 26, in a semiconductor device 9′ according to this embodiment, a base 160, ribs 170, 170, a transparent member 194′, and an encapsulating resin 196 are exposed at a pair of side surfaces of the semiconductor device 9′, as in the eighth embodiment. In addition, as in the ninth embodiment, the encapsulating resin 196 extends to external edges of the ribs 170, 170, and no spacers are provided.

Fabrication of the semiconductor device 9′ of this embodiment differs from that of the semiconductor device 9 of the ninth embodiment only in that a single long transparent member 194′ replaces the transparent members 194 and is placed on, and bonded to, a plurality of semiconductor elements 10, 10, . . . in the process step of fabricating the semiconductor device 9 of the ninth embodiment, and that the transparent member 194′ is cut, together with the ribs 170, 170, the encapsulating resin 196, and other components, to form individual semiconductor devices 9′.

This embodiment has the same advantages as those of the eighth and ninth embodiments.

### OTHER EMBODIMENTS

The foregoing embodiments are merely examples of the present invention, and do not limit the present invention. For example, the semiconductor device for use in the optical pickup module described in the second embodiment may be replaced by one of the semiconductor devices of the first embodiment or the third through tenth embodiments.

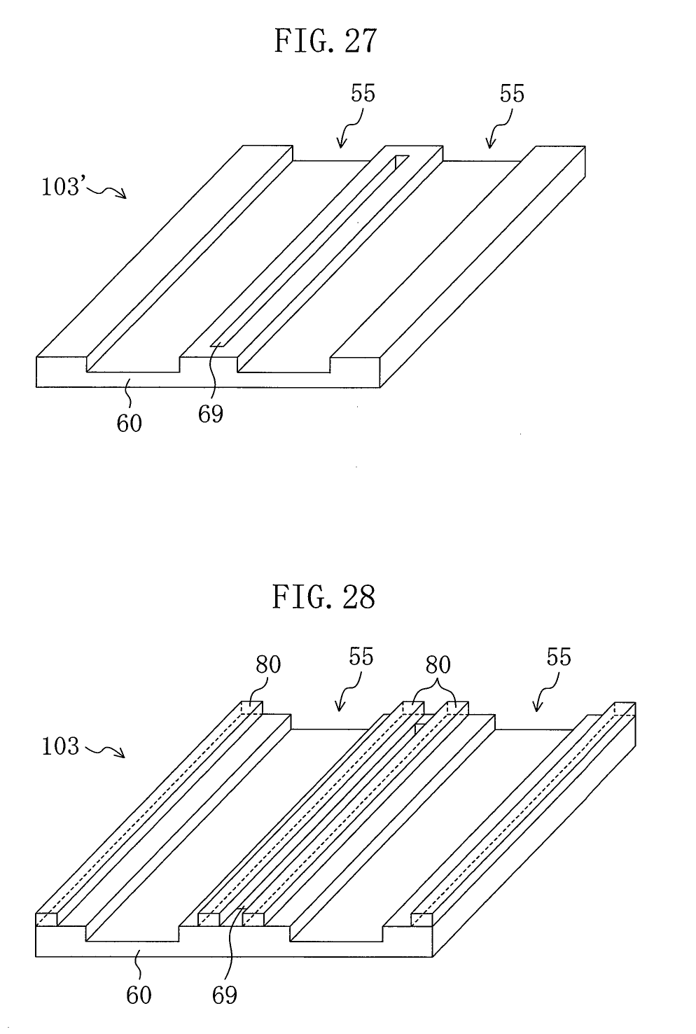

A package-assembled board 103 in which a slit 69 is provided between adjacent trenches 55, 55 as illustrated in FIG. 28 may be used as the package-assembled boards of the first through fifth embodiments. This package-assembled board 103 is formed by providing spacers 80, 80, . . . on a package-assembled board prototype 103′ illustrated in FIG. 27. The use of such a package-assembled board 103 can suppress warping or deforming of the package-assembled board 103 even with an increase (in the area) of the package-assembled board 103, and allows the trenches 55, 55 to be very easily separated from each other with the dicing saw 40 for a short period of time, resulting in easy processing. In the sixth embodiment and the subsequent embodiments, a package-assembled board including similar slits may be employed.

The external-connection portions may be provided on an area except for the non-mounting surface of the board. For example, the external-connection portions may be provided on the rib external side wall surfaces, or may be continuously provided from the non-mounting surface to the rib external side wall surfaces. The external-connection portions and the connection electrodes do not need to be connected by internal interconnections provided in the ribs, and may be connected by wires provided along the side wall surfaces of the ribs.

The semiconductor element does not need to be a solid-state image sensor, and may be a photoreceiver such as a photocoupler or a light-emitting element such as an LED and a laser device. Further, the semiconductor element does not need to be an optical device, and may be a SAW device, an oscillator, a pressure sensor, an acceleration sensor, or a sound sensor, for example. In this case, the lid does not need to be transparent. Furthermore, the semiconductor element may be fabricated by MEMS.

### INDUSTRIAL APPLICABILITY

As described above, a method for fabricating a semiconductor device according to the present invention is useful as a method for efficiently fabricating a small-size semiconductor device and for fabricating, for example, a photodetector for use in an optical pickup module.

1. A method for fabricating a semiconductor device including a semiconductor element and a package on which the semiconductor element is mounted, the method comprising the steps of:
A: providing a plurality of parallel trenches in a flat pre-board plate, thereby forming a package-assembled board in which a plurality of packages are connected to one another;
B: placing a plurality of semiconductor elements in each of the trenches in a direction along which the trench extends; and
C: cutting the package-assembled board at a portion between adjacent two of the trenches.

2. The method of claim 1, wherein in step A, at least two of the trenches are formed at a time.

3. The method of claim 1, wherein in step A, the trenches are formed by mechanically digging in the pre-board plate.

4. The method of claim 1, wherein in step A, the trenches are formed by digging in the pre-board plate with a laser.

5. The method of one of claim 1, wherein the package-assembled board includes a plurality of connection electrodes arranged in two lines between adjacent two of the trenches along the trenches,
in step B, the semiconductor elements and the connection electrodes are connected to each other by metal wires, and
in step C, the two lines of the connection electrodes are separated from each other.

6. The method of claim 5, further comprising the step of providing a ridge member extending along the trenches between the two lines of the connection electrodes.

7. The method of claim 6, further comprising the step of placing a lid for covering each of the semiconductor elements on the ridge member across an associated one of the trenches, and bonding the lid to the ridge member, after step B.

8. The method of claim 5, further comprising the steps of:
D: placing a transparent member having a plate shape on each of the semiconductor elements; and
encapsulating the metal wires and a side wall surface of the transparent member with an encapsulating resin.

9. The method of claim 8, wherein in step D, the transparent member is commonly placed on the plurality of semiconductor elements.

10. The method of claim 1, wherein the package-assembled board includes a plurality of connection electrodes arranged on a bottom surface of each of the trenches along the trench,
in step B, the semiconductor elements and the connection electrodes are connected to each other by metal wires, and
in step C, the adjacent two of the trenches are separated from each other.

11. The method of claim 10, further comprising the step of providing a ridge member extending along the trenches between adjacent two of the trenches.

12. The method of claim 10, further comprising the step of placing a lid for covering each of the semiconductor elements across an associated one of the trenches, after step B.

13. The method of claim 10, further comprising the steps of:
D: placing a transparent member having a plate shape on each of the semiconductor elements; and
encapsulating the metal wires and a side wall surface of the transparent member with an encapsulating resin.

14. The method of claim 13, wherein in step D, the transparent member is commonly placed on the plurality of semiconductor elements.

15. A semiconductor device, comprising:
a semiconductor element; and
a package on which the semiconductor element is mounted, wherein
the semiconductor device is a substantially rectangular solid,
a bottom surface and a pair of opposite side surfaces of the semiconductor device are part of the package,
the package includes
a base which is substantially rectangular and has a mounting surface on which the semiconductor element is mounted, and
ribs respectively provided on a pair of opposite external edges of the mounting surface and extending along the pair of opposite external edges,
a plate-like transparent member is placed on the semiconductor element,
the semiconductor element is encapsulated with an encapsulating resin,
the base, the ribs, and the encapsulating resin are exposed at another pair of opposite side surfaces of the semiconductor device, and
the encapsulating resin and the transparent member are exposed at an upper surface of the semiconductor device.

16. The semiconductor device of claim 15, wherein the transparent member is also exposed at the another pair of opposite side surfaces of the semiconductor device.

17. An optical pickup module, comprising:
the semiconductor device recited in claim 15;
a laser module; and
a beam splitter, wherein
the semiconductor element included in the semiconductor device is a photoreceiver.

18. The optical pickup module of claim 17, further comprising a mirror and an objective lens.

19. The optical pickup module of claim 17, wherein the optical pickup module is placed under an information-recording surface of an optical disk, and
a direction along which the ribs extend is substantially perpendicular to the information-recording surface.

20. The optical pickup module of claim 17, wherein
the laser module includes:
a blue-violet laser device configured to emit light having a peak wavelength ranging from 385 nm to 425 nm, both inclusive; and
a dual-wavelength laser device configured to emit light having a peak wavelength ranging from 630 nm to 670 nm, both inclusive, and light having a peak wavelength ranging from 760 nm to 800 nm, both inclusive.
